(19) United States
(12) Patent Application Publication
(10) Pub. No.: US 2026/0344233 A1
(43) Pub. Date: Oct. 29, 2026

(54) Semiconductor Device, Display Device, Display Module, and Electronic Device

(71) Applicant: Semiconductor Energy Laboratory Co., Ltd., Kanagawa-ken (JP)

(72) Inventors: Shunpei YAMAZAKI, Tokyo (JP); Kenichi Okazaki, Atsugi (JP)

(73) Assignee: Semiconductor Energy Laboratory Co., Ltd., Kanagawa-ken (JP)

(21) Appl. No.: 19/715,489

(22) Filed: Jun. 22, 2026

Related U.S. Application Data
(63) Continuation of application No. 18/036,993, filed on Nov. 2, 2021.

(30) Foreign Application Priority Data
Nov. 17, 2020 (JP) 2020-190955

(51) Int. Cl. H10K 59/131; G09G 3/3266; G09G 3/3275; H10K 59/124; H10K 102/00

(52) U.S. Cl. CPC H10K 59/1315; G09G 3/3266; G09G 3/3275; H10K 59/124; H10K 2102/351

(57) ABSTRACT

Parasitic capacitance of a wiring in a display device is decreased. A display device having both a high definition and a high frame frequency is provided. A high-resolution display device is provided. A semiconductor device used in the display device includes a first resin layer between a first wiring and a transistor, a first insulating layer between the first resin layer and the transistor, a second resin layer between the transistor and a second wiring, and a second insulating layer between the second resin layer and the transistor. The first insulating layer and the second insulating layer include an inorganic insulating film containing nitrogen. Furthermore, the first resin layer and the second resin layer have lower permittivities than the first insulating layer and the second insulating layer, respectively, and are greater than or equal to five times and less than or equal to 100 times as thick as the first insulating layer and the second insulating layer, respectively.

This application is a continuation of copending U.S. application Ser. No. 18/036,993, filed on May 15, 2023 which is a 371 of international application PCT/IB2021/060110 filed on Nov. 2, 2021 which are all incorporated herein by reference.

### TECHNICAL FIELD

One embodiment of the present invention relates to a semiconductor device and a fabrication method thereof. One embodiment of the present invention relates to a display device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, a high-definition display device has been required. For example, full high definition (1920×1080 pixels) has been in the mainstream of home-use television devices (also referred to as televisions or television receivers). From now on, development of high-definition television devices for 4K (3840×2160 pixels), 8K (7680×4320 pixels), or the like has been expected.

High-definition display panels used in display portions of portable information terminals, such as mobile phones, smartphones, tablet terminals, and laptop PCs have also been developed.

As a semiconductor material that can be employed for a transistor used in a display device, an oxide semiconductor using a metal oxide has been attracting attention. For example, Patent Document 1 discloses a semiconductor device in which the field-effect mobility is increased by stacking a plurality of oxide semiconductor layers, containing indium and gallium in an oxide semiconductor layer serving as a channel in the plurality of oxide semiconductor layers, and making the proportion of indium higher than the proportion of gallium.

### REFERENCE

### Patent Document

[Patent Document 1] Japanese Published Patent Application No. 2014-7399

### SUMMARY OF THE INVENTION

### Problems to Be Solved by the Invention

In display devices each having the same screen size, the higher the definition is, the higher the pixel density becomes; thus, parasitic capacitance between wirings is increased. Furthermore, the higher the definition is, the larger the number of wirings intersecting with one wiring becomes; thus, parasitic capacitance is increased. When the parasitic capacitance of a wiring is large, a time constant of the wiring is increased, which makes it difficult to display an image at a high frame frequency.

An object of one embodiment of the present invention is to provide a display device with reduced parasitic capacitance of a wiring. An object of one embodiment of the present invention is to provide a display device having both a high definition and a high frame frequency. An object of one embodiment of the present invention is to provide a high-resolution display device. An object of one embodiment of the present invention is to provide a highly reliable display device or semiconductor device.

An object of one embodiment of the present invention is to provide a semiconductor device, a display device, a display module, an electronic device, or the like that has a novel structure. An object of one embodiment of the present invention is to provide a method for manufacturing the above-described display device or semiconductor device with high yield. An object of one embodiment of the present invention is to at least reduce at least one of problems of the conventional technique.

Note that the description of these objects does not preclude the existence of other objects. One embodiment of the present invention does not need to achieve all these objects. Note that objects other than these can be derived from the description of the specification, the drawings, the claims, and the like.

### Means for Solving the Problems

One embodiment of the present invention is a semiconductor device including a first wiring, a second wiring, and a transistor. The semiconductor device includes a first resin layer between the first wiring and the transistor. The semiconductor device includes a first insulating layer between the first resin layer and the transistor. The semiconductor device includes a second resin layer between the transistor and the second wiring. The semiconductor device includes a second insulating layer between the second resin layer and the transistor. The first insulating layer and the second insulating layer include an inorganic insulating film containing nitrogen. The first resin layer and the second resin layer have lower permittivities than the first insulating layer and the second insulating layer, respectively. The first resin layer and the second resin layer are greater than or equal to five times and less than or equal to 100 times as thick as the first insulating layer and the second insulating layer, respectively.

It is preferable that the first resin layer and the second resin layer contain the same material and have equivalent thicknesses. The thickness of the second resin layer is greater than or equal to 80% and less than or equal to 120% of the thickness of the first resin layer. Furthermore, the first resin layer and the second resin layer are preferably formed using the same material by the same deposition method.

It is preferable that the first insulating layer and the second insulating layer contain the same material and have equivalent thicknesses. The thickness of the second insulating layer is greater than or equal to 80% and less than or equal to 120% of the thickness of the first insulating layer. Furthermore, the first resin layer and the second resin layer are preferably formed using the same material by the same deposition method.

In the above, the transistor preferably includes a first gate electrode, a second gate electrode, a first gate insulating layer, a second gate insulating layer, and a semiconductor layer. In this case, the first gate insulating layer is positioned between the semiconductor layer and the first gate electrode. The second gate insulating layer is positioned between the semiconductor layer and the second gate electrode. The first gate electrode and the second gate electrode includes a region where they overlap with each other with the semiconductor layer therebetween. The first gate electrode is electrically connected to the first wiring in an opening portion provided in the first insulating layer and the first resin layer.

In the above, it is preferable that the second wiring be electrically connected to the semiconductor layer in an opening portion provided in the second resin layer and the second insulating layer.

In the above, the transistor preferably includes a first electrode between the second resin layer and the second insulating layer. Furthermore, it is preferable that the first electrode be electrically connected to part of the semiconductor layer in an opening portion provided in the second insulating layer. Moreover, it is preferable that the second wiring be electrically connected to the first electrode in an opening portion provided in the second resin layer.

In any of the above, it is preferable that the second gate electrode be electrically connected to the first gate electrode in an opening portion provided in the first gate insulating layer and the second gate insulating layer.

In any of the above, the semiconductor layer preferably contains oxygen and either one or both of indium and zinc. In this case, it is preferable that the semiconductor layer contain indium, gallium, and zinc, and an atomic ratio of indium be greater than or equal to twice as high as an atomic ratio of gallium and an atomic ratio of zinc be greater than or equal to twice as high as the atomic ratio of gallium in the semiconductor layer.

In any of the above, it is preferable that the first resin layer and the second resin layer each contain acrylic or polyimide.

One embodiment of the present invention is a display device including any of the above semiconductor devices, a pixel electrode, a source driver circuit, and a gate driver circuit. The display device preferably includes a third resin layer between the pixel electrode and the transistor. It is preferable that the first wiring be electrically connected to the source driver circuit and the second wiring be electrically connected to the gate driver circuit.

In the above, it is preferable that an organic EL element be further included. In this case, the pixel electrode is preferably an electrode of the organic EL element.

One embodiment of the present invention is a display module including any of the above display devices and a connector or an integrated circuit.

One embodiment of the present invention is an electronic device including the above display module and at least one of an antenna, a battery, a housing, a camera, a speaker, a microphone, a touch sensor, and an operation button.

### Effect of the Invention

According to one embodiment of the present invention, a display device with reduced parasitic capacitance of a wiring can be provided. A display device having both a high definition and a high frame frequency can be provided. A high-resolution display device can be provided. A highly reliable display device or semiconductor device can be provided.

According to one embodiment of the present invention, a semiconductor device, a display device, a display module, an electronic device, or the like that has a novel structure can be provided. A method for manufacturing the above-described display device or semiconductor device with high yield can be provided. According to one embodiment of the present invention, at least one of problems of the conventional technique can be at least reduced.

Note that the description of these effects does not preclude the existence of other effects. One embodiment of the present invention does not need to have all these effects. Effects other than these can be derived from the description of the specification, the drawings, the claims, and the like.

### BRIEF DESCRIPTION OF THE DRAWINGS

FIG. 1A to FIG. 1C are diagrams illustrating a structure example of a semiconductor device.

FIG. 2A and FIG. 2B are diagrams illustrating a structure example of a semiconductor device.

FIG. 3A and FIG. 3B are diagrams illustrating structure examples of a semiconductor device.

FIG. 4A to FIG. 4F are diagrams illustrating an example of a method for fabricating a semiconductor device.

FIG. 5A to FIG. 5D are diagrams illustrating an example of a method for fabricating a semiconductor device.

FIG. 6A to FIG. 6C are diagrams illustrating an example of a method for fabricating a semiconductor device.

FIG. 7A and FIG. 7B are diagrams illustrating an example of a method for fabricating a semiconductor device.

FIG. 8A and FIG. 8B are diagrams illustrating an example of a method for fabricating a semiconductor device.

FIG. 9A to FIG. 9C are diagrams illustrating a structure example of a display device.

FIG. 10A to FIG. 10C are diagrams illustrating a structure example of a pixel.

FIG. 11 is a diagram illustrating a structure example of a display device.

FIG. 12 is a diagram illustrating a structure example of a display device.

FIG. 13A to FIG. 13F are diagrams illustrating structure examples of an electronic device.

FIG. 14A and FIG. 14B are diagrams illustrating a structure example of a display module.

FIG. 15A and FIG. 15B are diagrams illustrating a structure example of an electronic device.

FIG. 16A to FIG. 16E are diagrams illustrating structure examples of electronic devices.

FIG. 17A to FIG. 17G are diagrams illustrating structure examples of electronic devices.

FIG. 18A to FIG. 18D are diagrams illustrating structure examples of electronic devices.

### MODE FOR CARRYING OUT THE INVENTION

Hereinafter, embodiments will be described with reference to the drawings. Note that the embodiments can be implemented in many different modes, and it will be readily understood by those skilled in the art that modes and details thereof can be changed in various ways without departing from the spirit and scope thereof. Thus, the present invention should not be construed as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

In each drawing described in this specification, the size, the layer thickness, or the region of each component is exaggerated for clarity in some cases. Therefore, they are not limited to the illustrated scale.

In this specification and the like, the ordinal numbers such as “first” and “second” are used in order to avoid confusion among components and do not limit the number.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes replaced with each other when a transistor of opposite polarity is used or when the direction of current is changed in circuit operation, for example. Therefore, the terms “source” and “drain” can be switched in this specification.

In this specification and the like, the term “film” and the term “layer” can be interchanged with each other. For example, in some cases, the term “conductive layer” and the term “insulating layer” can be interchanged with the term “conductive film” and the term “insulating film”, respectively.

In this specification and the like, a display panel that is one embodiment of a display device has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, a semiconductor device of one embodiment of the present invention, a fabrication method thereof, a display device, and the like will be described. In particular, in this embodiment, as an example of the semiconductor device, a transistor using an oxide semiconductor for a semiconductor layer in which a channel is formed will be described.

### Structure Example

### Structure Example 1

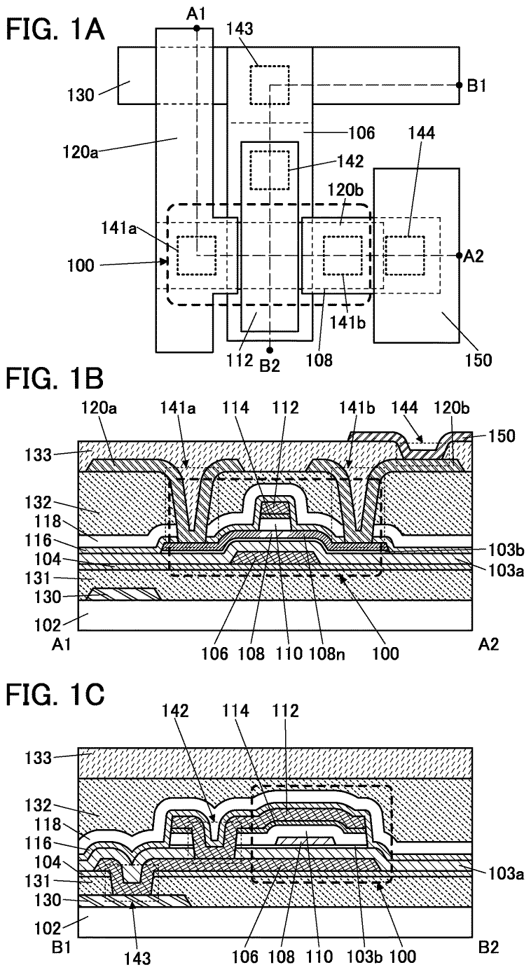

FIG. 1A is a schematic top view of a semiconductor device including a transistor 100. FIG. 1B corresponds to a cross-sectional view taken along a dashed-dotted line A1-A2 in FIG. 1A, and FIG. 1C corresponds to a cross-sectional view taken along a dashed-dotted line B1-B2 in FIG. 1A. Note that in FIG. 1A, some components (e.g., a gate insulating layer) are not illustrated. Furthermore, FIG. 1B and FIG. 1C are cross-sectional views including a cross section in the channel length direction and a cross section in the channel width direction of the transistor 100, respectively.

The transistor 100 is provided over a substrate 102 and includes a conductive layer 106, an insulating layer 103a, an insulating layer 103b, a semiconductor layer 108, an insulating layer 110, a metal oxide layer 114, a conductive layer 112, and the like. A resin layer 131 is provided between the transistor 100 and the substrate 102. A resin layer 132 is provided over the transistor 100. An insulating layer 104 is provided between the resin layer 131 and the transistor 100. An insulating layer 116 and an insulating layer 118 are provided to be stacked between the transistor 100 and the resin layer 132.

In the transistor 100, part of the conductive layer 106 and part of the conductive layer 112 each function as a gate electrode. Furthermore, part of the insulating layer 103a, part of the insulating layer 103b, and part of the insulating layer 110 each function as a gate insulating layer.

A conductive layer 130 functioning as a wiring is provided between the substrate 102 and the resin layer 131. Furthermore, a conductive layer 120a and a conductive layer 120b are provided over the resin layer 132. At least one of the conductive layer 120a and the conductive layer 120b functions as a wiring.

A resin layer 133 is provided to cover the resin layer 132, the conductive layer 120a, and the conductive layer 120b. Furthermore, a conductive layer 150 is provided over the resin layer 133. For example, the conductive layer 150 can be used as a pixel electrode of a display element. Alternatively, the conductive layer 150 may be used as a wiring. The conductive layer 150 is electrically connected to the conductive layer 120b in an opening portion 144 provided in the resin layer 133.

The insulating layer 104 functions as a barrier film that prevents an impurity such as water or hydrogen in the resin layer 131 from diffusing into the transistor 100. Similarly, the insulating layer 116 also functions as a barrier film that prevents an impurity such as water or hydrogen in the resin layer 132 from diffusing into the transistor 100. In such a manner, the transistor 100 is surrounded by the insulating layer 104 and the insulating layer 116, whereby a highly reliable semiconductor device can be achieved even with a structure in which the transistor 100 is sandwiched between the resin layers from above and below.

An inorganic insulating film through which water or hydrogen does not easily diffuse can be used as each of the insulating layer 104 and the insulating layer 116. For example, an insulating film containing a nitride such as silicon nitride, silicon nitride oxide, silicon oxynitride, aluminum nitride, or aluminum nitride oxide can be favorably used. Specifically, because of having a blocking property against any one or both of hydrogen and oxygen, silicon nitride can prevent both diffusion of hydrogen from the outside into the semiconductor layer 108 and release of oxygen from the semiconductor layer 108 to the outside, and can achieve a highly reliable transistor.

An organic resin can be used for the resin layer 131 and the resin layer 132. In particular, using acrylic or polyimide is preferable. Note that a material that can be used for the resin layer 131 is not limited thereto, and a material that is chemically or thermally stable can be used.

The resin layer 131 and the resin layer 132 each preferably function as a planarization film. For example, a film formed by a coating method such as a spin coating method or a slit coating method is preferable. When the resin layer 131 functions as a planarization film, the influence of a step of the conductive layer 130 positioned on the side closer to the substrate 102 than the transistor 100 can be inhibited, a surface where the transistor 100 is formed can be planarized, and thus variation in electrical characteristics of the transistor 100 can be reduced. Furthermore, when the resin layer 132 functions as a planarization film, the influence of a step of the transistor 100 can be inhibited, surfaces where the conductive layer 120a and the conductive layer 120b are formed can be planarized, and thus processing defects in these layers can be reduced. In addition, a surface where the conductive layer 150 that can be used as a pixel electrode and the like is formed can be planarized, and thus variation in electrical characteristics and optical characteristics of a display element using the conductive layer 150 for a pixel electrode can be reduced.

Each of the resin layer 131 and the resin layer 132 preferably has a low permittivity. Specifically, an organic insulating material having a lower permittivity than either one or both of the insulating layer 104 and the insulating layer 116 is preferably used. In particular, the resin layer 131 and the resin layer 132 preferably have lower permittivities than the insulating layer 104 and the insulating layer 116.

Furthermore, the resin layer 131 and the resin layer 132 are preferably formed to be thick. For example, each of the resin layer 131 and the resin layer 132 is preferably thicker than either one or both of the insulating layer 104 and the insulating layer 116. In particular, the resin layer 131 and the resin layer 132 are preferably thicker than the insulating layer 104 and the insulating layer 116. Specifically, the resin layer 131 and the resin layer 132 can each be greater than or equal to five times and less than or equal to 100 times, greater than or equal to five times and less than or equal to 50 times, or greater than or equal to five times and less than or equal to 30 times as thick as the insulating layer 104 or the insulating layer 116. As a more specific example, the thicknesses of the insulating layer 104 and the insulating layer 116 can be greater than or equal to 50 nm and less than or equal to 300 nm, and the thicknesses of the resin layer 131 and the resin layer 132 can be greater than or equal to 500 nm and less than or equal to 20 μm, preferably greater than or equal to 1 μm and less than or equal to 10 μm.

The left side in FIG. 1B illustrates a cross section in an intersection portion of the conductive layer 130 and the conductive layer 120a illustrated in FIG. 1A.

At least the resin layer 131 and the resin layer 132 are provided between the conductive layer 130 and the conductive layer 120a. Since each of the resin layer 131 and the resin layer 132 has a low permittivity and is formed to be thick, the capacitance generated between the conductive layer 130 and the conductive layer 120a in the intersection portion thereof can be extremely small. Accordingly, a high-definition and high-resolution display device that can be driven at a high frame rate.

Since the parasitic capacitance between the wirings can be reduced, the number of pixels connected to one wiring can be large, whereby a high-definition display device can be achieved. The definition corresponding to full high definition (also referred to as “2K definition,” “2K1K,” “2K,” and the like), ultra high definition (also referred to as “4K definition,” “4K2K,” “4K,” and the like), or super high definition (also referred to as “8K definition,” “8K4K,” “8K,” and the like) can be achieved.

Furthermore, the small parasitic capacitance between the wirings can inhibit an increase in time constants of the wirings even with an increased resolution, whereby a high-resolution display device can be achieved. A high-resolution display device can be achieved, and the resolution of the display device can be higher than or equal to 400 ppi, higher than or equal to 500 ppi, preferably higher than or equal to 1000 ppi, further preferably higher than or equal to 2000 ppi, still further preferably higher than or equal to 3000 ppi, and less than or equal to 10000 ppi, less than or equal to 7500 ppi, or less than or equal to 6000 ppi, for example. Note that the above structure is preferably employed because a display device having a resolution lower than 400 ppi can also have reduced parasitic capacitance. For example, the above structure can be suitably used for a large display device with a screen diagonal size of greater than or equal to 50 inches, greater than or equal to 60 inches, or greater than or equal to 70 inches.

Furthermore, since the time constant of the wiring can be reduced, the time taken for charging and discharging (e.g., writing time of a pixel) can be shortened; therefore, driving at a high frame rate can be performed. For example, 60 Hz driving, 120 Hz driving, 180 Hz driving, and 240 Hz driving can be expected.

It is preferable that the resin layer 131 and the resin layer 132 contain the same material and have equivalent thicknesses. Alternatively, the thickness of the resin layer 132 is preferably greater than or equal to 80% and less than or equal to 120% of the thickness of the resin layer 131. Furthermore, the resin layer 131 and the resin layer 132 are preferably formed using the same material by the same deposition method.

When a pair of resin layers 131 and 132 including the transistor 100 therebetween is formed using the same material to have substantially equivalent thicknesses, stress can be substantially equivalent. Accordingly, since the stress can be substantially equivalent above and below the transistor 100, an extreme stress difference does not occur; as a result, film separation (pealing) during the process can be inhibited. Furthermore, the stress applied to the transistor 100 from the upper side and the lower side can be uniform, and thus variation in electrical characteristics of the transistor 100 can be reduced.

Similarly, it is preferable that the insulating layer 104 and the insulating layer 116 contain the same material and their thicknesses be equivalent. Alternatively, the thickness of the insulating layer 116 is preferably greater than or equal to 80% and less than or equal to 120% of the thickness of the insulating layer 104. Furthermore, the insulating layer 104 and the insulating layer 116 are preferably formed using the same material by the same deposition method. Accordingly, not only film separation during the process is more effectively inhibited, but also variation in the electrical characteristics of the transistor 100 can be reduced.

The conductive layer 106 is provided over the insulating layer 104. The insulating layer 103a is provided to cover the conductive layer 106. The insulating layer 103b is provided over the insulating layer 103a. The semiconductor layer 108 having an island-like shape is provided over the insulating layer 103b and overlaps with part of the conductive layer 106. The insulating layer 110, the metal oxide layer 114, and the conductive layer 112 are provided to be stacked in this order over the semiconductor layer 108 and the insulating layer 103b and each include a portion overlapping with the semiconductor layer 108 and the conductive layer 106. The insulating layer 116 is provided to cover the insulating layer 103a, the semiconductor layer 108, the insulating layer 110, the metal oxide layer 114, and the conductive layer 112. The insulating layer 118 is provided over the insulating layer 116.

The semiconductor layer 108 includes a region overlapping with the conductive layer 112 and a pair of low-resistance regions 108n between which the region is sandwiched. A region of the semiconductor layer 108 that overlaps with the conductive layer 112 functions as a channel formation region of the transistor 100. Meanwhile, the pair of low-resistance regions 108n function as a source region and a drain region of the transistor 100.

An insulating film containing nitrogen is preferably used as the insulating layer 103a positioned on the conductive layer 106 side. Meanwhile, an insulating film containing oxygen is preferably used as the insulating layer 103b in contact with the semiconductor layer 108. The insulating layer 103a and the insulating layer 103b are preferably deposited successively without exposure to the air with a plasma CVD apparatus.

As the insulating layer 103a, an insulating film containing nitrogen, such as a silicon nitride film, a silicon nitride oxide film, an aluminum nitride film, or a hafnium nitride film, can be used, for example.

As the insulating layer 103b in contact with the semiconductor layer 108, it is preferable to use a dense insulating film on a surface of which an impurity such as water is less likely to be adsorbed. In addition, it is preferable to use an insulating film which includes as few defects as possible and in which an impurity such as water or hydrogen is reduced.

For the insulating layer 103b, for example, an insulating layer including one or more kinds of a silicon oxide film, a silicon oxynitride film, a silicon nitride oxide film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film can be used. In particular, a silicon oxide film or a silicon oxynitride film is preferably used.

The insulating layer 103b that is in contact with the semiconductor layer 108 preferably includes an oxide insulating film. The insulating layer 103b further preferably includes a region containing oxygen in excess of that in the stoichiometric composition. In other words, the insulating layer 103b includes an insulating film capable of releasing oxygen. It is also possible to supply oxygen into the insulating layer 103b by forming the insulating layer 103b in an oxygen atmosphere, performing heat treatment on the deposited insulating layer 103b in an oxygen atmosphere, performing plasma treatment or the like on the deposited insulating layer 110 in an oxygen atmosphere, or depositing an oxide film (e.g., a metal oxide film that is to be the semiconductor layer 108) over the insulating layer 103b in an oxygen atmosphere, for example. Note that an oxidizing gas (e.g., dinitrogen monoxide or ozone) may be used instead of oxygen or in addition to oxygen in each of the above treatments for supplying oxygen.

The semiconductor layer 108 contains a metal oxide exhibiting semiconductor characteristics (hereinafter, also referred to as an oxide semiconductor). The semiconductor layer 108 preferably contains at least indium and oxygen. When the semiconductor layer 108 contains an oxide of indium, the carrier mobility can be increased. For example, a transistor that can flow a higher current than a transistor using amorphous silicon can be provided.

A region in the semiconductor layer 108 overlapping with the conductive layer 112 functions as a channel formation region. Furthermore, the semiconductor layer 108 preferably includes the pair of low-resistance regions 108n with the channel formation region sandwiched therebetween. Each of the low-resistance regions 108n has higher carrier concentration than the channel formation region and function as a source region or a drain region.

The low-resistance regions 108n can also be referred to as regions with lower resistance, regions having a higher carrier concentration, regions having a larger amount of oxygen vacancies, regions having a higher hydrogen concentration, or regions having a higher impurity concentration than the channel formation region.

Here, the composition of the semiconductor layer 108 is described. The semiconductor layer 108 preferably contains a metal oxide containing at least indium and oxygen. Moreover, the semiconductor layer 108 may contain zinc additionally. The semiconductor layer 108 may contain gallium.

Typically, an indium oxide, an indium zinc oxide (In—Zn oxide), an indium gallium zinc oxide (also denoted as In—Ga—Zn oxide or IGZO), or the like can be used for the semiconductor layer 108. Alternatively, an indium tin oxide (In—Sn oxide), an indium tin oxide containing silicon, or the like can be used.

Here, the composition of the semiconductor layer 108 greatly affects the electrical characteristics, reliability, and the like of the transistor 100. For example, an increase in the indium content in the semiconductor layer 108 can increase the carrier mobility and achieve a transistor with high field-effect mobility.

Here, one of indexes for evaluating the reliability of a transistor is a gate bias stress test (GBT) in which a state of applying an electric field to a gate is maintained. Among GBTs, a test in which a state where a positive potential relative to a source potential and a drain potential is supplied to a gate is maintained at high temperatures is referred to as a PBTS (Positive Bias Temperature Stress) test, and a test in which a state where a negative potential is supplied to a gate is maintained at high temperatures is referred to as an NBTS (Negative Bias Temperature Stress) test. The PBTS test and the NBTS test conducted in a state where irradiation with light such as white LED light is performed are respectively referred to as a PBTIS (Positive Bias Temperature Illumination Stress) test and an NBTIS (Negative Bias Temperature Illumination Stress) test.

In particular, in an n-channel transistor using an oxide semiconductor, a positive potential is applied to a gate in putting the transistor in an on state (a state where a current flows); thus, the amount of change in threshold voltage in the PBTS test is one important item to be focused on as an indicator of the reliability of the transistor.

Here, the use of a metal oxide film not containing gallium or having a low gallium content in the composition of the semiconductor layer 108 can reduce the amount of change in the threshold voltage in the PBTS test. In the case where gallium is contained, the gallium content is preferably lower than the indium content in the composition of the semiconductor layer 108. Thus, a highly reliable transistor can be achieved.

Specifically, in the case where an In—Ga—Zn oxide is used for the semiconductor layer 108, a metal oxide film whose atomic proportion of In is higher than the atomic proportion of Ga can be used as the semiconductor layer 108. It is further preferable to use a metal oxide film whose atomic proportion of Zn is higher than the atomic proportion of Ga. In other words, a metal oxide film in which the atomic proportions of metal elements satisfy In>Ga and Zn>Ga is preferably used as the semiconductor layer 108.

For example, a metal oxide film having any of the following atomic ratios of metal elements can be used as the semiconductor layer 108: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=5:2:5, and a neighborhood thereof.

Alternatively, as the semiconductor layer 108, a film that is deposited by a sputtering method using a metal oxide target in which the atomic ratios of metal elements are in the above range is preferable. In this case, the composition of the deposited semiconductor layer 108 might deviate from the composition of the metal oxide target.

A metal oxide film not containing gallium may be used as the semiconductor layer 108. For example, an In—Zn oxide can be used as the semiconductor layer 108. In this case, when the atomic proportion of In to metal elements contained in the metal oxide film is increased, the field-effect mobility of the transistor can be increased. By contrast, when the atomic proportion of Zn to metal elements contained in the metal oxide is increased, the metal oxide film has high crystallinity; thus, a change in the electrical characteristics of the transistor can be inhibited and the reliability can be increased. Alternatively, a metal oxide film that contains neither gallium nor zinc, such as indium oxide, can be used as the semiconductor layer 108. The use of a metal oxide film not containing gallium at all can make a change in the threshold voltage particularly in the PBTS test extremely small.

For example, an oxide film of indium oxide, indium zinc oxide, indium tin oxide, or the like can be used as the semiconductor layer 108.

Although the case of using gallium is described typically, the above description can also be applied in the case where the element M (M is one or more selected from aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium) is used instead of gallium. Specifically, M is preferably one or more selected from gallium, aluminum, yttrium, and tin.

It is preferable to use a metal oxide film having crystallinity as the semiconductor layer 108. For example, a metal oxide film having a CAAC (c-axis aligned crystal) structure, which is described later, a polycrystalline structure, a microcrystalline structure, or the like can be used. With the use of a metal oxide film having crystallinity as the semiconductor layer 108, the density of defect states in the semiconductor layer 108 can be reduced, which enables the semiconductor device to have high reliability.

As the semiconductor layer 108 has higher crystallinity, the density of defect states in the film can be lower. By contrast, the use of a metal oxide film with low crystallinity enables a transistor to flow a large amount of current.

In the case where the metal oxide film is deposited by a sputtering method, the crystallinity of the deposited metal oxide film can be increased as the substrate temperature (stage temperature) at the time of deposition is higher. The crystallinity of the deposited metal oxide film can be increased as the proportion of a flow rate of an oxygen gas to the whole deposition gas (also referred to as oxygen flow rate ratio) used at the time of deposition is higher.

The low-resistance region 108n of the semiconductor layer 108 is a region containing an impurity element. Examples of the impurity element include hydrogen, boron, carbon, nitrogen, fluorine, phosphorus, sulfur, arsenic, aluminum, and a rare gas. Note that typical examples of a rare gas include helium, neon, argon, krypton, and xenon. In particular, boron or phosphorus is preferably contained. Alternatively, two or more of these elements may be contained.

The low-resistance region 108n preferably includes a region where the impurity concentration is higher than or equal to 1×10¹⁹ atoms/cm³ and lower than or equal to 1×10²³ atoms/cm³, preferably higher than or equal to 5×10¹⁹ atoms/cm³ and lower than or equal to 5×10²² atoms/cm³, further preferably higher than or equal to 1×10²⁰ atoms/cm³ and lower than or equal to 1×10²² atoms/cm³.

The concentrations of the impurities contained in the low-resistance regions 108n can be analyzed by an analysis method such as secondary ion mass spectrometry (SIMS) or X-ray photoelectron spectroscopy (XPS), for example. In the case of using XPS analysis, ion sputtering from the front surface side or the back surface side is combined with XPS analysis, whereby the concentration distribution in the depth direction can be found.

The top surface shapes of the conductive layer 112, the metal oxide layer 114, and the insulating layer 110 are processed to be substantially the same.

Note that in this specification and the like, the expression “having substantially the same top surface shapes” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “top surface shapes are substantially aligned with each other”.

As an insulating film that can be used as the insulating layer 110, the above description of the insulating layer 103b can be referred to.

The metal oxide layer 114 positioned between the insulating layer 110 and the conductive layer 112 functions as a barrier film that prevents diffusion of oxygen contained in the insulating layer 110 to the conductive layer 112 side. The metal oxide layer 114 also functions as a barrier film that prevents diffusion of hydrogen or water contained in the conductive layer 112 to the insulating layer 110 side. The metal oxide layer 114 is preferably formed using, for example, a material that is less likely to transmit oxygen and hydrogen than at least the insulating layer 110.

Even in the case where a metal material that is likely to absorb oxygen, such as aluminum or copper, is used for the conductive layer 112, the metal oxide layer 114 can prevent diffusion of oxygen from the insulating layer 110 into the conductive layer 112. Furthermore, even in the case where the conductive layer 112 contains hydrogen, diffusion of hydrogen from the conductive layer 112 into the semiconductor layer 108 through the insulating layer 110 can be prevented. Consequently, carrier density in a channel formation region of the semiconductor layer 108 can be extremely low.

For the metal oxide layer 114, an insulating material or a conductive material can be used. When the metal oxide layer 114 has an insulating property, the metal oxide layer 114 functions as part of the gate insulating layer. Meanwhile, when the metal oxide layer 114 has conductivity, the metal oxide layer 114 functions as part of the gate electrode.

The metal oxide layer 114 is preferably formed using an insulating material with a higher permittivity than silicon oxide. It is particularly preferable to use an aluminum oxide film, a hafnium oxide film, a hafnium aluminate film, or the like because driving voltage can be lowered.

For the metal oxide layer 114, a conductive oxide such as indium oxide, indium tin oxide (ITO), or indium tin oxide containing silicon (ITSO) can also be used, for example. A conductive oxide containing indium is particularly preferable because of its high conductivity.

For the metal oxide layer 114, an oxide material containing one or more elements that are the same as those of the semiconductor layer 108 is preferably used. It is particularly preferable to use an oxide semiconductor material that can be used for the semiconductor layer 108. In that case, a metal oxide film formed using the same sputtering target as that for the semiconductor layer 108 is preferably used as the metal oxide layer 114 because an apparatus can be shared.

In addition, the metal oxide layer 114 is preferably formed using a sputtering apparatus. For example, in the case where an oxide film is formed using a sputtering apparatus, forming the oxide film in an atmosphere containing an oxygen gas can suitably supply oxygen into the insulating layer 110 or the semiconductor layer 108.

The insulating layer 116 is provided in contact with top surfaces of the low-resistance regions 108n. The insulating layer 116 preferably has a function of reducing the resistance of the low-resistance regions 108n. As the insulating layer 116, an insulating film that can supply impurities to the low-resistance regions 108n by being heated at the time of or after the deposition of the insulating layer 116 can be used. Alternatively, an insulating film that can generate oxygen vacancies in the low-resistance regions 108n by being heated at the time of or after the deposition of the insulating layer 116 can be used. Alternatively, an insulating film that can cause a distortion in the low-resistance regions 108n by heating at the time of or after the deposition of the insulating layer 116 can be used.

For example, as the insulating layer 116, an insulating film functioning as a supply source that supplies impurities to the low-resistance regions 108n can be used. In that case, the insulating layer 116 is preferably a film from which hydrogen is released by heating. When such an insulating layer 116 is formed in contact with the semiconductor layer 108, impurities such as hydrogen can be supplied to the low-resistance regions 108n, so that the resistance of the low-resistance regions 108n can be reduced.

The insulating layer 116 is preferably a film deposited using a gas containing an impurity element such as a hydrogen element as a deposition gas used for the deposition. In addition, as the deposition temperature of the insulating layer 116 is decreased, a large amount of impurity elements can be effectively supplied to the semiconductor layer 108. The deposition temperature of the insulating layer 116 is higher than or equal to 200 °C and lower than or equal to 500 °C, preferably higher than or equal to 220 °C and lower than or equal to 450 °C, further preferably higher than or equal to 230 °C and lower than or equal to 400 °C, for example.

When the insulating layer 116 is deposited under a reduced pressure while heating is performed, release of oxygen from regions to be the low-resistance regions 108n in the semiconductor layer 108 can be promoted. When an impurity such as hydrogen is supplied to the semiconductor layer 108 where many oxygen vacancies are formed, the carrier concentration of the low-resistance regions 108n is increased, and the resistance of the low-resistance regions 108n can be lowered more effectively.

For the insulating layer 116, for example, an insulating film containing a nitride, such as silicon nitride, silicon nitride oxide, silicon oxynitride, aluminum nitride, or aluminum nitride oxide can be favorably used. In particular, because of having a blocking property against hydrogen, oxygen, or the like, silicon nitride can prevent both a diffusion of hydrogen from the outside into the semiconductor layer and a release of oxygen from the semiconductor layer to the outside, and thus a highly reliable transistor can be achieved. Alternatively, an insulating film containing an oxide such as silicon oxide, aluminum oxide, or hafnium oxide can be used.

The insulating layer 118 functions as a protective layer protecting the transistor 100. For example, an inorganic insulating material such as an oxide or a nitride can be used for the insulating layer 110. More specifically, for example, an inorganic insulating material such as silicon oxide, silicon oxynitride, silicon nitride, silicon nitride oxide, aluminum oxide, aluminum oxynitride, aluminum nitride, hafnium oxide, or hafnium aluminate can be used.

Note that one of the insulating layer 116 and the insulating layer 118 is not necessarily provided. Alternatively, the stacking order of the insulating layer 116 and the insulating layer 118 may be changed.

Part of the conductive layer 120a and part of the conductive layer 120b provided over the resin layer 132 are electrically connected to the low-resistance regions 108n in the transistor 100, and can be said that they function as a source electrode and a drain electrode. The conductive layer 120a and the conductive layer 120b are electrically connected to the low-resistance regions 108n through an opening portion 141a and an opening portion 141b, respectively, which are provided in the resin layer 132, the insulating layer 118, and the insulating layer 116.

Here, an example is shown in which the conductive layer 112, the conductive layer 106, and the conductive layer 130 are electrically connected to each other. The conductive layer 112 and the conductive layer 106 are electrically connected to each other in an opening portion 142 provided in the metal oxide layer 114, the insulating layer 110, the insulating layer 103b, and the insulating layer 103a. Furthermore, the conductive layer 106 and the conductive layer 130 are electrically connected to each other in an opening portion 143 provided in the insulating layer 104 and the resin layer 131.

Note that although an example where both of the pair of gate electrodes are electrically connected to the conductive layer 130 is shown, any one of them may be electrically connected to the conductive layer 130. For example, in the case where the conductive layer 130 and the conductive layer 112 are electrically connected to each other not through the conductive layer 106, the conductive layer 130 and the conductive layer 106 are electrically connected to each other through a relay electrode formed by processing the same conductive film as the conductive layer 106. Alternatively, an opening portion reaching a top surface of the conductive layer 130 from the metal oxide layer 114 may be formed to connect the conductive layer 112 directly to the conductive layer 130.

When the conductive layer 106 is not provided below the semiconductor layer 108, the transistor may include only one gate (such a transistor is also referred to as a single-gate transistor). In this case, the transistor can be what is called a top-gate transistor that includes a gate above the semiconductor layer 108 where a channel is formed. For example, in FIG. 1C, when a right end portion of the conductive layer 106 is formed to be positioned between the opening portion 142 and the semiconductor layer 108, a single-gate transistor can be achieved.

### Structure Example 2

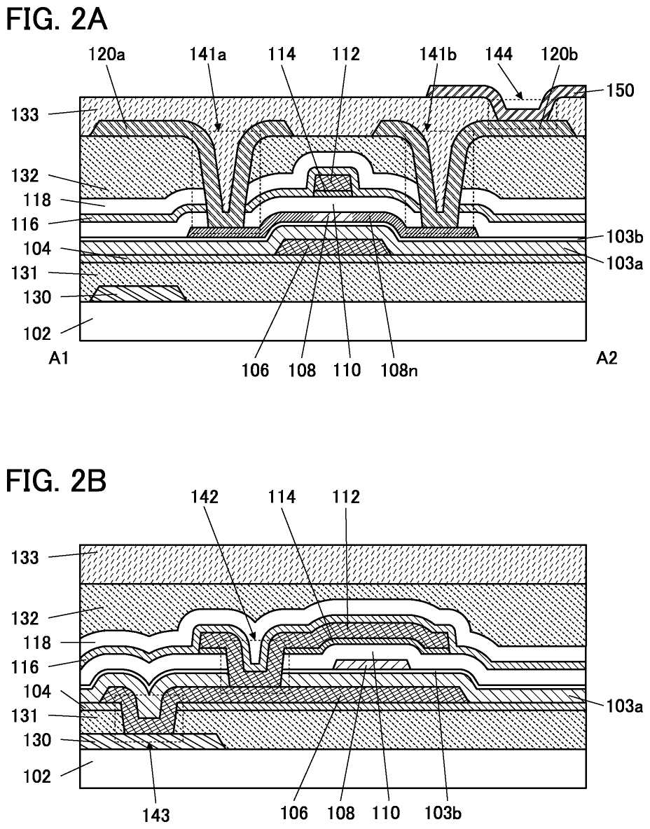

FIG. 2A and FIG. 2B illustrate a structure example partly different from the structure example 1. The structure illustrated in FIG. 2A and FIG. 2B is different from the structure example 1 mainly in the shape of the insulating layer 110.

The insulating layer 110 is provided to cover a top surface of the insulating layer 103b and a top surface and a side surface of the semiconductor layer 108. The insulating layer 110 is provided in contact with not only the channel formation region of the semiconductor layer 108 but also top surfaces of the low-resistance regions 108n.

The low-resistance regions 108n can be formed in such a manner that after forming the insulating layer 110, the metal oxide layer 114, and the conductive layer 112, an impurity or the like is supplied through the insulating layer 110 using the conductive layer 112 as a mask. For example, by plasma treatment, a plasma ion doping method, or an ion implantation method, the above impurity element can be supplied to the semiconductor layer 108 through the insulating layer 110.

With such a structure of the insulating layer 110, coverage of the insulating layer 116 in the vicinity of an end portion of the conductive layer 112 can be improved, and thus reliability and manufacturing yield can be improved.

### Structure Example 3

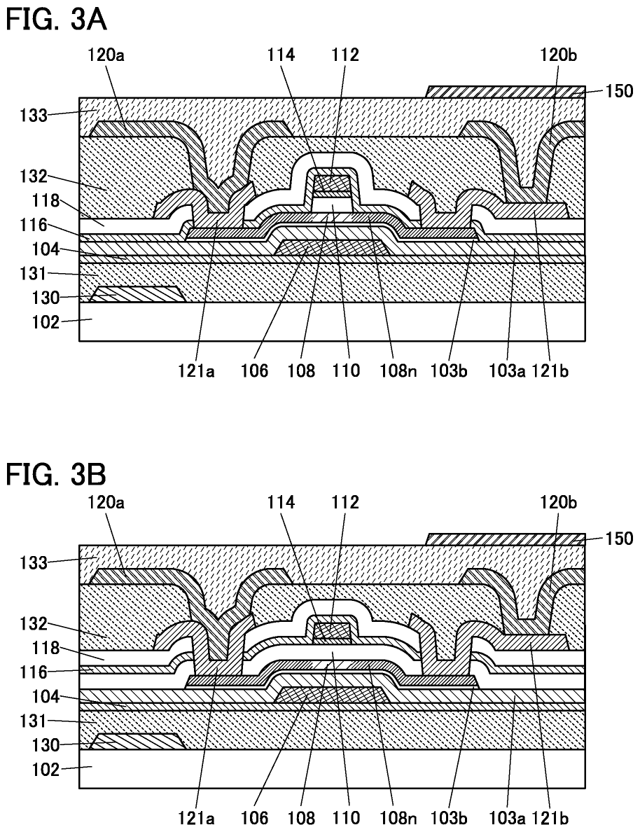

The structure illustrated in FIG. 3A is different from the structure example 1 mainly in including a conductive layer 121a and a conductive layer 121b.

The conductive layer 120a is electrically connected to the low-resistance region 108n through the conductive layer 121a. The conductive layer 120b is electrically connected to the low-resistance region 108n through the conductive layer 121b. Therefore, each of the conductive layer 121a and the conductive layer 121b can be referred to as a relay wiring.

The conductive layer 121a and the conductive layer 121b are provided between the insulating layer 118 and the resin layer 132. The conductive layer 121a and the conductive layer 121b are each electrically connected to the low-resistance region 108n in the opening portion provided in the insulating layer 118 and the insulating layer 116.

The conductive layer 120a and the conductive layer 120b are electrically connected to the conductive layer 121a and the conductive layer 121b, respectively, in opening portions provided in the resin layer 132.

In such a manner, when the conductive layer 121a and the conductive layer 121b functioning as relay wirings are provided between the insulating layer 118 and the resin layer 132, a deep contact hole does not need to be formed; thus, manufacturing yield can be improved. For example, in the case where the opening is formed in the resin layer 132 containing a resin and the insulating layer 118 and the insulating layer 116 including an inorganic insulating film in a series of processes, not only the processing conditions are strictly limited, but also a defect such as the disappearance of the semiconductor layer 108 positioned in a bottom portion of the opening portion or a large opening diameter might be caused.

FIG. 3A illustrates an example where in the connection portion between the conductive layer 120a and the conductive layer 121a, the opening portion provided in the resin layer 132 overlaps with the opening portion provided in the insulating layer 118 and the insulating layer 116. Alternatively, as the connection portion between the conductive layer 120b and the conductive layer 121b, the two opening portions can be shifted to different portions such that they do not overlap with each other.

FIG. 3B illustrates an example of the case where the conductive layer 121a and the conductive layer 121 b are applied to the structure exemplified in the structure example 2. The conductive layer 121a and the conductive layer 121b are each electrically connected to the low-resistance region 108n in the opening portion provided in the insulating layer 118, the insulating layer 116, and the insulating layer 110.

### Manufacturing Method Example

An example of a method for fabricating the above-exemplified semiconductor device will be described below with reference to drawings. Here, the description is made with the semiconductor device exemplified in the structure example 2, FIG. 2A, and FIG. 2B as an example.

Note that thin films that constitute the semiconductor device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

The thin films that constitute the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that constitute the semiconductor device are processed, a photolithography method or the like can be used for the processing. Besides, a nanoimprinting method, a sandblasting method, a lift-off method, or the like may be used for the processing of the thin films. Island-shaped thin films may be directly formed by a deposition method using a blocking mask such as a metal mask.

There are two typical examples of a photolithography method. In one of the methods, a resist mask is formed over a thin film that is to be processed, the thin film is processed by etching or the like, and the resist mask is removed. In the other method, a photosensitive thin film is deposited and then processed into a desired shape by light exposure and development.

As the light used for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Exposure may be performed by liquid immersion exposure technique. Furthermore, as the light used for the exposure, extreme ultra-violet (EUV) light or X-rays may be used. Instead of the light used for the exposure, an electron beam can also be used. Extreme ultra-violet light, X-rays, or an electron beam is preferably used to enable extremely minute processing. Note that in the case of performing exposure by scanning of a beam such as an electron beam, a photomask is not needed.

For etching of the thin film, a dry etching method, a wet etching method, a sandblasting method, or the like can be used.

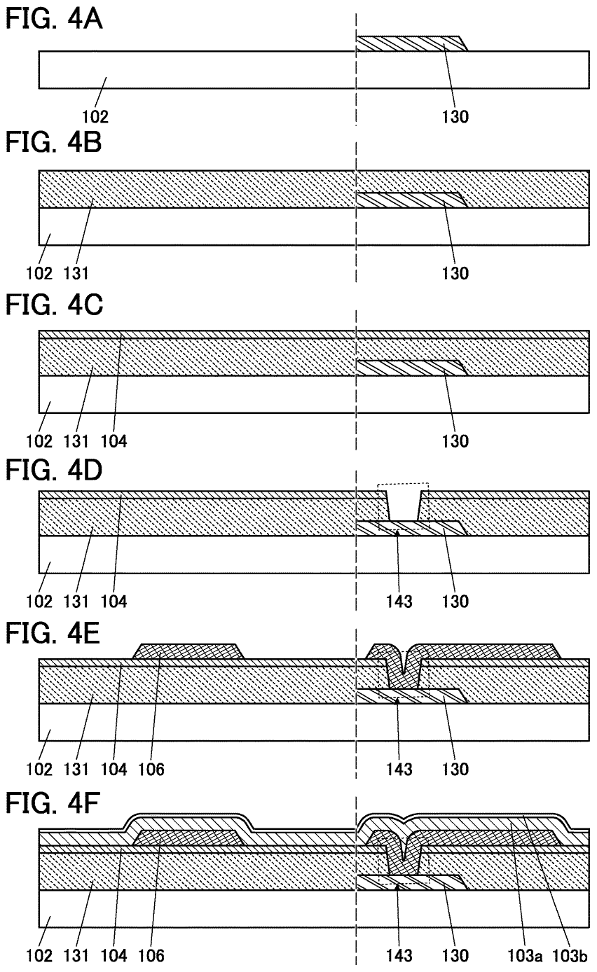

FIG. 4A to FIG. 8B each illustrate a cross section of the semiconductor device exemplified in the structure example 2 in the channel length direction and the channel width direction in each step of the fabrication process.

### Formation of Conductive Layer 130

A conductive film is deposited over the substrate 102 and processed by etching, whereby the conductive layer 130 functioning as a wiring is formed (FIG. 4A).

At this time, the resin layer 131 formed later functions as a planarization film and its coverage is extremely high; thus, the conductive layer 130 does not necessarily have a tapered shape. Furthermore, since the conductive layer 130 can also be thick, wiring resistance of a wiring as which the conductive layer 130 is used can be reduced.

When a conductive film containing copper is used as the conductive film to be the conductive layer 106, wiring resistance can be reduced. For example, a conductive film containing copper is preferably used in the case of a large display device or a display device with a high definition. Even in the case where a conductive film containing copper is used as the conductive layer 106, diffusion of copper to the semiconductor layer 108 side can be suppressed by the insulating layer 103a, whereby a highly reliable transistor can be obtained.

### Formation of Resin Layer 131

Then, the resin layer 131 is formed to cover the substrate 102 and the conductive layer 130 (FIG. 4B).

For example, for the resin layer 131, a mixed material of a resin precursor and a solvent is formed over the support substrate by a method such as spin coating, dipping, spray coating, ink-jetting, dispensing, screen printing, offset printing, a doctor knife, slit coating, roll coating, curtain coating, or knife coating. After that, heat treatment is performed to remove the solvent and the like and cure the material, so that the resin layer 131 containing an organic resin can be formed.

As an organic resin that can be used for the resin layer 131, polyimide can be typically used. Polyimide is preferable because of its excellent heat resistance. Acrylic, epoxy, polyamide, polyimide-amide, siloxane, a benzocyclobutene-based resin, a phenol resin, or the like can also be used.

For example, in the case where polyimide is used, a resin precursor that can generate an imide bond by dehydration can be used. Alternatively, a material containing soluble polyimide may be used.

As the organic resin used for the resin layer 131, either a photosensitive resin or a nonphotosensitive resin may be used. Photosensitive polyimide is a material that is suitably used for a planarization film or the like of a display panel, and therefore, the formation apparatus, the material, and the like can be shared. Thus, there is no need to prepare a new apparatus, a new material, and the like in order to achieve the structure of one embodiment of the present invention. With the use of a photosensitive resin material, when exposure and development treatment are performed, an opening portion can be formed or an unnecessary portion can be removed, for example. Moreover, by optimization of a light exposure method, light exposure conditions, and the like, an uneven shape can be formed on a surface. For example, a multiple light exposure technique or a light exposure technique using a half-tone mask or a gray-tone mask is used.

### Formation of Insulating Layer 104

Next, the insulating layer 104 is formed over the resin layer 131 (FIG. 4C). The insulating layer 104 can be formed by a PECVD method, an ALD method, a sputtering method, or the like.

### Formation of Opening Portion 143

Then, a resist mask is formed over the insulating layer 104 and part of the insulating layer 104 is removed by etching, whereby an opening is formed in the insulating layer 104. Next, an opening reaching the conductive layer 130 is formed in part of the resin layer 131 using the insulating layer 104 as a hard mask, whereby the opening portion 143 is formed (FIG. 4D).

As described above, the use of the insulating layer 104 as a hard mask can make a diameter of the opening portion 143 small. At this time, the resist mask used in processing the insulating layer 104 is preferably removed after the etching of the insulating layer 104. The resin layer 131 is preferably etched by dry etching. For example, etching can be performed by ashing treatment using plasma.

Note that the opening portion 143 may be formed by the following method that is different from the above. First, a photosensitive material is used for the resin layer 131 and exposure and development are performed, whereby the resin layer 131 provided with an opening overlapping with the conductive layer 130 is formed. After the insulating layer 104 is deposited, a portion overlapping with the opening in the resin layer 131 is removed by etching, whereby the opening portion 143 can be formed. In this method, the process of etching the thick resin layer 131 can be omitted.

### Formation of Conductive Layer 106

Next, a conductive film is deposited to cover the insulating layer 104 and the opening portion 143 and then processed by etching, whereby the conductive layer 106 functioning as a gate electrode is formed (FIG. 4E).

At this time, as illustrated in FIG. 4E, the conductive layer 106 is preferably processed so as to have an end portion with a tapered shape. This can improve step coverage with the insulating layer 103a to be formed next.

When a conductive film containing copper is used as the conductive film to be the conductive layer 106, wiring resistance can be reduced.

### Formation of Insulating Layer 103a and Insulating Layer 103b

Next, the insulating layer 103a and the insulating layer 103b are formed to cover the insulating layer 104 and the conductive layer 106 (FIG. 4F). The insulating layer 103a and the insulating layer 103b can be formed by a PECVD method, an ALD method, a sputtering method, or the like.

Here, the insulating layer 103a and the insulating layer 103b are formed to be stacked. In particular, each of the insulating layer 103a and the insulating layer 103b is preferably formed by a PECVD method.

After the insulating layer 103b is formed, treatment for supplying oxygen to the insulating layer 103b may be performed. For example, plasma treatment, heat treatment, or the like in an oxygen atmosphere can be performed. Alternatively, oxygen may be supplied to the insulating layer 103b by a plasma ion doping method, an ion implantation method, or the like.

### Formation of Semiconductor Layer 108

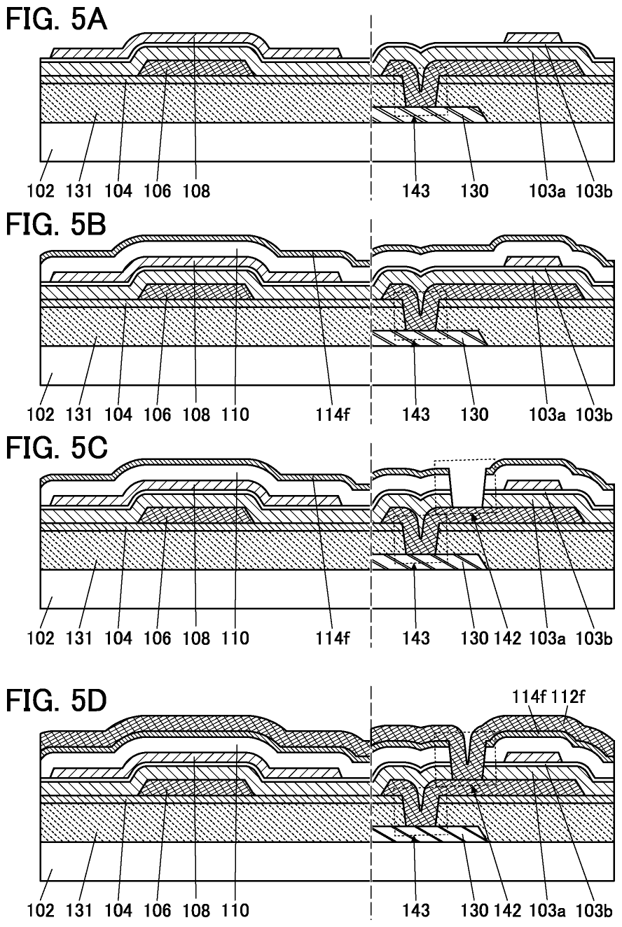

Next, a metal oxide film is deposited over the insulating layer 103b and part of the metal oxide film is etched to form the semiconductor layer 108 having an island shape (FIG. 5A).

The metal oxide film is preferably formed by a sputtering method using a metal oxide target.

The metal oxide film is preferably a dense film with as few defects as possible. The metal oxide film is preferably a highly purified film in which an impurity such as hydrogen or water is reduced as much as possible. It is particularly preferable to use a metal oxide film having crystallinity.

In addition, an oxygen gas and an inert gas (such as a helium gas, an argon gas, or a xenon gas) may be mixed in depositing the metal oxide film. Note that when the proportion of an oxygen gas in the whole deposition gas (hereinafter, also referred to as oxygen flow rate ratio) at the time of depositing the metal oxide film is higher, the crystallinity of the metal oxide film can be higher and a transistor with higher reliability can be obtained. By contrast, when the oxygen flow rate ratio is lower, the crystallinity of the metal oxide film is lower and a transistor with a higher on-state current can be obtained.

In depositing the metal oxide film, as the substrate temperature becomes higher, a denser metal oxide film having higher crystallinity can be formed. By contrast, a lower substrate temperature can lead to lower crystallinity and higher electric conductivity of the formed metal oxide film.

The metal oxide film is formed under the deposition conditions where the substrate temperature is higher than or equal to room temperature and lower than or equal to 250 °C, preferably higher than or equal to room temperature and lower than or equal to 200 °C, further preferably higher than or equal to room temperature and lower than or equal to 140 °C. For example, the substrate temperature is preferably higher than or equal to room temperature and lower than 140 °C, in which case high productivity is achieved. Furthermore, when the metal oxide film is deposited with the substrate temperature set at room temperature or without heating the substrate intentionally, the crystallinity can be made low.

It is preferable to perform at least one of treatment for desorbing water, hydrogen, an organic substance, or the like adsorbed onto a surface of the insulating layer 103b and treatment for supplying oxygen into the insulating layer 103b before the deposition of the metal oxide film. For example, heat treatment can be performed at a temperature higher than or equal to 70 °C and lower than or equal to 200 °C in a reduced-pressure atmosphere. Alternatively, plasma treatment may be performed in an oxygen-containing atmosphere. Alternatively, oxygen may be supplied to the insulating layer 103b by plasma treatment in an atmosphere containing an oxidizing gas such as dinitrogen monoxide (N₂O). Performing plasma treatment containing a dinitrogen monoxide gas can supply oxygen to the insulating layer 103b while suitably removing an organic substance on the surface of the insulating layer 103b. After such treatment, the metal oxide film is preferably deposited successively without exposure of the surface of the insulating layer 103b to the air.

Note that in the case where the semiconductor layer 108 has a stacked-layer structure in which a plurality of metal oxide films are stacked, it is preferable that after the metal oxide film formed earlier is formed, the next metal oxide film be formed successively without exposure of a surface of the metal oxide film formed earlier to the air.

For processing of the metal oxide film, either one or both of a wet etching method and a dry etching method are used. At this time, part of the insulating layer 103b that does not overlap with the semiconductor layer 108 is etched and thinned in some cases. For example, in some cases, the insulating layer 103b is removed by etching and a surface of the insulating layer 103a is exposed.

Here, it is preferable that heat treatment be performed after the metal oxide film is deposited or after the metal oxide film is processed into the semiconductor layer 108. By the heat treatment, hydrogen or water contained in the metal oxide film or the semiconductor layer 108 or adsorbed on the surface of the metal oxide film or the semiconductor layer 108 can be removed. The film quality of the metal oxide film or the semiconductor layer 108 is improved (e.g., the number of defects is reduced or crystallinity is increased) by the heat treatment in some cases.

Oxygen can be supplied from the insulating layer 103b to the metal oxide film or the semiconductor layer 108 by the heat treatment. At this time, it is further preferable that the heat treatment be performed before the metal oxide film is processed into the semiconductor layer 108.

The temperature of the heat treatment can be typically higher than or equal to 150 °C and lower than the strain point of the substrate, higher than or equal to 200 °C and lower than or equal to 500 °C, higher than or equal to 250 °C and lower than or equal to 450 °C, or higher than or equal to 300 °C and lower than or equal to 450 °C.

The heat treatment can be performed in an atmosphere containing a rare gas or nitrogen. Alternatively, heating may be performed in the atmosphere, and then heating may be performed in an oxygen-containing atmosphere. Alternatively, heating may be performed in a dry air atmosphere. It is preferable that the atmosphere of the above heat treatment contain hydrogen, water, or the like as little as possible. An electric furnace, an RTA (Rapid Thermal Anneal) apparatus, or the like can be used for the heat treatment. The use of the RTA apparatus can shorten the heat treatment time.

Note that the heat treatment is not necessarily performed. The heat treatment is not necessarily performed in this step, and heat treatment performed in a later step may also serve as the heat treatment in this step. In some cases, treatment at a high temperature (e.g., deposition step) or the like in a later step can serve as the heat treatment in this step.

### Formation of Insulating Layer 110

Next, the insulating layer 110 is formed to cover the insulating layer 103b and the semiconductor layer 108.

The insulating layer 110 is preferably formed by a PECVD method.

It is preferable to perform plasma treatment on the surface of the semiconductor layer 108 before deposition of the insulating layer 110. By the plasma treatment, impurities adsorbed onto the surface of the semiconductor layer 108, such as water, can be reduced. Thus, impurities at the interface between the semiconductor layer 108 and the insulating layer 110 can be reduced, achieving a highly reliable transistor. The plasma treatment is particularly suitable in the case where the surface of the semiconductor layer 108 is exposed to the air after the formation of the semiconductor layer 108 before the deposition of the insulating layer 110. For example, the plasma treatment can be performed in an atmosphere containing oxygen, ozone, nitrogen, dinitrogen monoxide, argon, or the like. The plasma treatment and the deposition of the insulating layer 110 are preferably performed successively without exposure to the air.

After the insulating layer 110 is deposited, heat treatment is preferably performed. By the heat treatment, hydrogen or water contained in the insulating layer 110 or adsorbed on its surface can be removed. At the same time, the number of defects in the insulating layer 110 can be reduced.

For the conditions of the heat treatment, the above description can be referred to.

Note that the heat treatment is not necessarily performed. The heat treatment is not necessarily performed in this step, and heat treatment performed in a later step may also serve as the heat treatment in this step. In some cases, treatment at a high temperature (e.g., deposition step) or the like in a later step can serve as the heat treatment in this step.

### Formation of Metal Oxide Film 114f

Next, a metal oxide film 114f is formed over the insulating layer 110 (FIG. 5B).

The metal oxide film 114f is preferably deposited in an oxygen-containing atmosphere, for example. It is particularly preferable that the metal oxide film 114f be formed by a sputtering method in an oxygen-containing atmosphere. In that case, oxygen can be supplied to the insulating layer 110 at the time of depositing the metal oxide film 114f. Note that oxygen may be supplied to the semiconductor layer 108 at the time of depositing the metal oxide film 114f.

The above description of the semiconductor layer 108 can be referred to for the case where the metal oxide film 114f is formed by a sputtering method using an oxide target containing a metal oxide as in the case of the semiconductor layer 108.

For example, as deposition conditions of the metal oxide film 114f, a metal oxide film may be formed by a reactive sputtering method with a metal target using oxygen as a deposition gas. When aluminum is used for the metal target, for example, an aluminum oxide film can be deposited.

At the time of depositing the metal oxide film 114f, the amount of oxygen supplied into the insulating layer 110 can be increased with a higher proportion of the oxygen flow rate to the total flow rate of the deposition gas introduced into a deposition chamber of a deposition apparatus (a higher oxygen flow rate ratio) or with higher oxygen partial pressure in the deposition chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure in the deposition chamber be as close to 100% as possible.

When the metal oxide film 114f is formed by a sputtering method in an oxygen-containing atmosphere in the above manner, oxygen can be supplied to the insulating layer 110 and release of oxygen from the insulating layer 110 can be prevented during the deposition of the metal oxide film 114f. As a result, an extremely large amount of oxygen can be enclosed in the insulating layer 110.

After the deposition of the metal oxide film 114f, heat treatment is preferably performed. By the heat treatment, oxygen contained in the insulating layer 110 can be supplied to the semiconductor layer 108. When the heat treatment is performed while the metal oxide film 114f covers the insulating layer 110, oxygen can be prevented from being released from the insulating layer 110 to the outside, and a large amount of oxygen can be supplied to the semiconductor layer 108. Thus, the oxygen vacancies in the semiconductor layer 108 can be reduced, leading to a highly reliable transistor.

For the conditions of the heat treatment, the above description can be referred to.

Note that the heat treatment is not necessarily performed. The heat treatment is not necessarily performed in this step, and heat treatment performed in a later step may also serve as the heat treatment in this step. In some cases, treatment at a high temperature (e.g., deposition step) or the like in a later step can serve as the heat treatment in this step.

After the deposition of the metal oxide film 114f or the heat treatment, the metal oxide film 114f may be removed.

### Formation of Opening Portion 142

Next, the metal oxide film 114f, the insulating layer 110, the insulating layer 103b, and the insulating layer 103a are partly etched to form the opening portion 142 reaching the conductive layer 106 (FIG. 5C). Accordingly, the conductive layer 112 to be formed later can be electrically connected to the conductive layer 106 through the opening portion 142.

### Formation of Conductive Layer 112 and Metal Oxide Layer 114

Next, a conductive film 112f to be the conductive layer 112 is deposited over the metal oxide film 114f (FIG. 5D).

For the conductive film 112f, a low-resistance metal or a low-resistance alloy material is preferably used. It is preferable that the conductive film 112f be formed using a material from which hydrogen is less likely to be released and in which hydrogen is less likely to be diffused. Furthermore, a material that is less likely to be oxidized is preferably used for the conductive film 112f.

For example, the conductive film 112f is preferably deposited by a sputtering method using a sputtering target containing a metal or an alloy.

For example, the conductive film 112f is preferably a stacked-layer film including a low-resistance conductive film and a conductive film which is less likely to be oxidized and in which hydrogen is less likely to be diffused.

Next, the conductive film 112f and the metal oxide film 114f are partly etched to form the conductive layer 112 and the metal oxide layer 114. The conductive film 112f and the metal oxide film 114f are preferably processed using the same resist mask. Alternatively, the metal oxide film 114f may be etched using the conductive layer 112 after etching as a hard mask.

In particular, a wet etching method is preferably employed for etching the conductive film 112f and the metal oxide film 114f.

In such a manner, the conductive layer 112 and the metal oxide layer 114 that have substantially the same top surface shapes can be formed.

As described above, the insulating layer 110 is not etched to make such a structure that the top surface and the side surface of the semiconductor layer 108 and the insulating layer 103b are covered, which can prevent the semiconductor layer 108, the insulating layer 103b, and the like from being etched and thinned in etching the conductive film 112f or the like.

### Treatment for Supplying Impurity Element

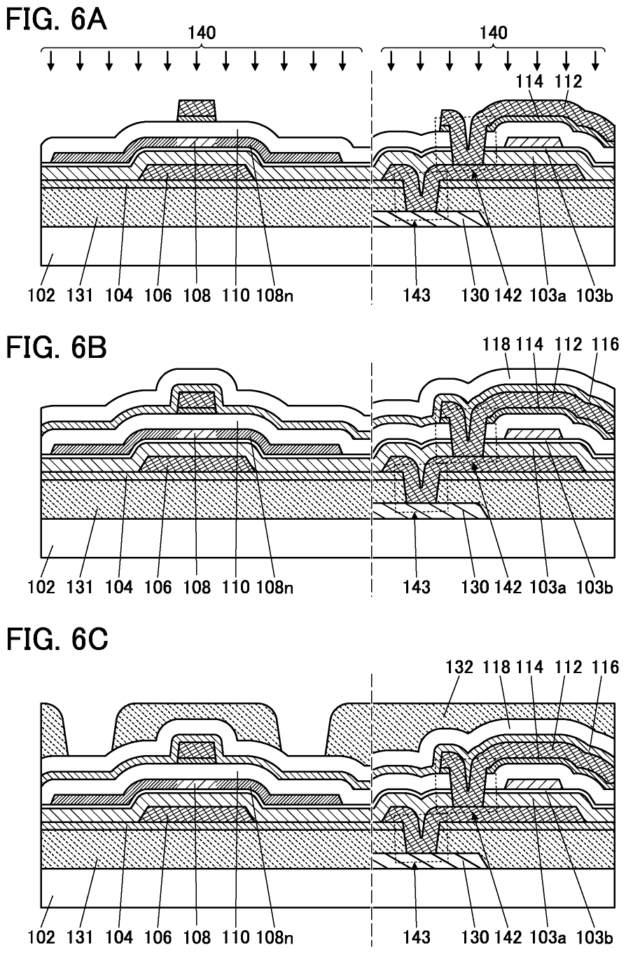

Next, treatment for supplying (adding or injecting) an impurity element 140 to the semiconductor layer 108 through the insulating layer 110 is performed with the use of conductive layer 112 as a mask (FIG. 6A). Thus, the low-resistance regions 108n can be formed in regions of the semiconductor layer 108 that are not covered with the conductive layer 112. At this time, the conditions of the treatment for supplying the impurity element 140 are preferably determined in consideration of the material, thickness, or the like of the conductive layer 112 serving as the mask and the like so that the impurity element 140 is supplied as little as possible to the region of the semiconductor layer 108 that overlaps with the conductive layer 112. In this manner, a channel formation region with a sufficiently reduced impurity concentration can be formed in the region of the semiconductor layer 108 that overlaps with the conductive layer 112.

A plasma ion doping method or an ion implantation method can be suitably used for the supply of the impurity element 140. In these methods, the concentration profile in the depth direction can be controlled with high accuracy by the acceleration voltage and the dosage of ions, or the like. The use of a plasma ion doping method can increase productivity. In addition, the use of an ion implantation method with mass separation can increase the purity of the impurity element to be supplied.

In the treatment for supplying the impurity element 140, treatment conditions are preferably controlled such that the concentration is the highest at the interface between the semiconductor layer 108 and the insulating layer 110, a portion in the semiconductor layer 108 near the interface, or a portion in the insulating layer 110 near the interface. Accordingly, the impurity element 140 at an optimal concentration can be supplied to both the semiconductor layer 108 and the insulating layer 110 in one treatment.

Examples of the impurity element 140 include hydrogen, boron, carbon, nitrogen, fluorine, phosphorus, sulfur, arsenic, aluminum, magnesium, silicon, and a rare gas. Note that typical examples of a rare gas include helium, neon, argon, krypton, and xenon. It is particularly preferable to use boron, phosphorus, aluminum, magnesium, or silicon.

As a source gas of the impurity element 140, a gas containing any of the above impurity elements can be used. In the case where boron is supplied, typically, a B₂H₆ gas, a BF₃ gas, or the like can be used. In the case where phosphorus is supplied, typically, a PH₃ gas can be used. A mixed gas in which any of these source gases is diluted with a rare gas may be used.

Besides, any of CH₄, N₂, NH₃, AlH₃, AlCl₃, SiH₄, Si₂H₆, F₂, HF, H₂, (C₅H₅)₂Mg, a rare gas, and the like can be used as the source gas. An ion source is not limited to a gas, and a solid or a liquid that is vaporized by heating may be used.

Addition of the impurity element 140 can be controlled by setting the conditions such as the acceleration voltage and the dosage in consideration of the compositions, densities, thicknesses, and the like of the insulating layer 110 and the semiconductor layer 108.

In the case where boron or phosphorus is added by an ion implantation method or a plasma ion doping method, the dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity element 140 is not limited thereto; treatment using thermal diffusion by heating, plasma treatment, or the like may be used, for example. In a plasma treatment method, plasma is generated in a gas atmosphere containing an impurity element to be added and plasma treatment is performed, so that the impurity element can be added. A dry etching apparatus, an ashing apparatus, a plasma CVD apparatus, a high-density plasma CVD apparatus, or the like can be used as an apparatus for generating the plasma.

In one embodiment of the present invention, the impurity element 140 can be supplied to the semiconductor layer 108 through the insulating layer 110. Thus, even in the case where the semiconductor layer 108 has crystallinity, damage on the semiconductor layer 108 is reduced at the time of supplying the impurity element 140, and degradation of crystallinity can be inhibited. Therefore, this is suitable for the case where a reduction in crystallinity increases electric resistance.

### Formation of Insulating Layer 116 and Insulating Layer 118

Next, the insulating layer 116 and the insulating layer 118 are formed to cover the insulating layer 110, the metal oxide layer 114, and the conductive layer 112 (FIG. 6B).

When the insulating layer 116 and the insulating layer 118 are formed by a plasma CVD method at a too high deposition temperature, impurities contained in the low-resistance regions 108n and the like might be diffused into a peripheral portion including the channel formation region of the semiconductor layer 108. Furthermore, electric resistance of the low-resistance regions 108n might be increased. Thus, the deposition temperature for the insulating layer 116 and the insulating layer 118 is determined in consideration of these.

The deposition temperatures of the insulating layer 116 and the insulating layer 118 are preferably higher than or equal to 150 °C and lower than or equal to 400 °C, further preferably higher than or equal to 180 °C and lower than or equal to 360 °C, still further preferably higher than or equal to 200 °C and lower than or equal to 250 °C, for example. The deposition of the insulating layer 116 and the insulating layer 118 at low temperatures enables the transistor to have favorable electrical characteristics even when the transistor has a short channel length.

Heat treatment may be performed after the formation of the insulating layer 116 and the insulating layer 118. The heat treatment can allow the low-resistance region 108n to have low resistance more stably, in some cases. For example, by the heat treatment, the impurity element 140 diffuses moderately and homogenized locally, so that the low-resistance regions 108n having an ideal concentration gradient of the impurity element can be formed. Note that when the temperature of the heat treatment is too high (e.g., higher than or equal to 500 °C), the impurity element 140 is also diffused into the channel formation region, so that the electrical characteristics and reliability of the transistor might be degraded.

For the conditions of the heat treatment, the above description can be referred to.

Note that the heat treatment is not necessarily performed. The heat treatment is not necessarily performed in this step, and heat treatment performed in a later step may also serve as the heat treatment in this step. In the case where treatment at a high temperature is performed in a later step (e.g., deposition step), such treatment can sometimes serve as the heat treatment in this step.

### Formation of Resin Layer 132

Next, the resin layer 132 including an opening portion is formed over the insulating layer 118 (FIG. 6C).

The above description of the resin layer 131 can be referred to for a material that can be used for the resin layer 132. Here, a photosensitive material is used and exposure and development are performed, whereby the resin layer 132 provided with an opening is formed.

### Formation of Opening Portion 141a and Opening Portion 141b

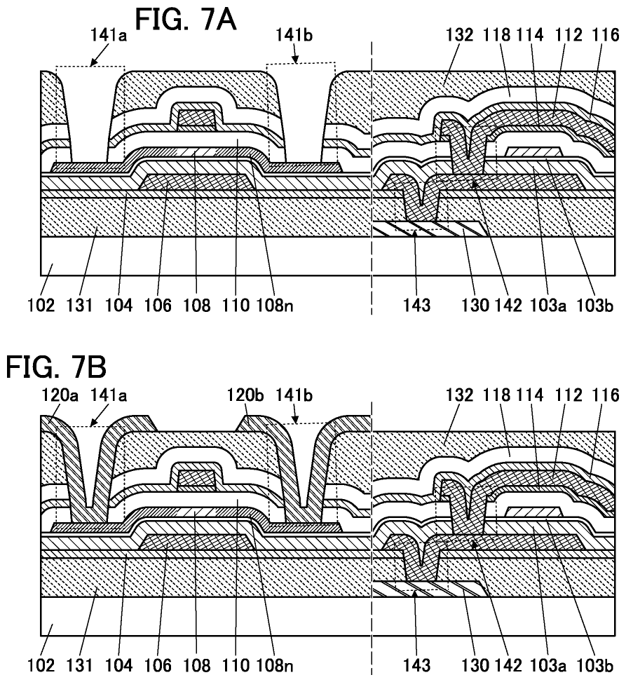

Next, the insulating layer 118, the insulating layer 116, and the insulating layer 110 are partly etched in a region overlapping with the opening portion in the resin layer 132, whereby the opening portion 141a and the opening portion 141b that reach the low-resistance regions 108n are formed (FIG. 7A).

Here, portions of the insulating layer 118, the insulating layer 116, and the insulating layer 110 that are positioned in the opening in the resin layer 132 are etched using the resin layer 132 as an etching mask.

Note that the opening portion 141a and the opening portion 141b may be formed by the following method that is different from the above. First, before the formation of the resin layer 132, a resist mask is formed over the insulating layer 118, and an opening is formed in the insulating layer 118, the insulating layer 116, and the insulating layer 110 in advance. Next, a photosensitive material is used and exposure and development are performed, whereby the resin layer 132 including an opening is formed. Therefore, the opening portion 141a and the opening portion 141b can be formed.

### Formation of Conductive Layer 120a and Conductive Layer 120b

Next, a conductive film is deposited over the resin layer 132 to cover the opening portion 141a and the opening portion 141b, and the conductive film is processed into a desired shape, so that the conductive layer 120a and the conductive layer 120b are formed (FIG. 7B).

Through the above process, the semiconductor device provided with the transistor can be manufactured.

### Formation of Resin Layer 133

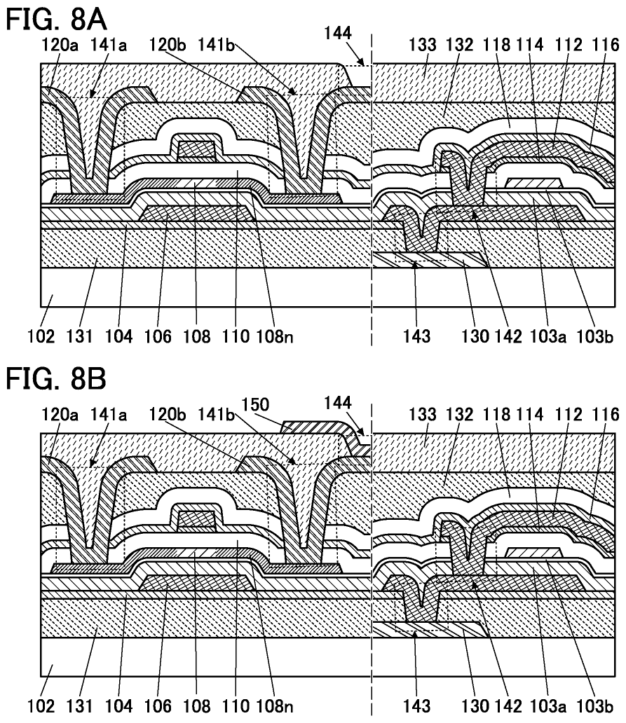

Next, the resin layer 133 including the opening portion 144 is formed to cover the conductive layer 120a, the conductive layer 120b, and the resin layer 132 (FIG. 8A).

The description of the resin layer 131 and the resin layer 132 can be referred to for the details of the resin layer 133.

### Formation of Conductive Layer 150

Next, a conductive film is deposited over the resin layer 133 so as to cover the opening portion 144, and the conductive film is processed into a desired shape, whereby the conductive layer 150 is formed (FIG. 8B).

The above is the description of the fabrication method example.

### Components of Semiconductor Device

Components included in the semiconductor device of this embodiment are described below.

### Substrate

Although there is no particular limitation on a material and the like of the substrate 102, it is necessary that the substrate have heat resistance high enough to withstand at least heat treatment performed later. For example, a single crystal semiconductor substrate or a polycrystalline semiconductor substrate containing silicon or silicon carbide as a material, a compound semiconductor substrate of silicon germanium or the like, an SOI substrate, a glass substrate, a ceramic substrate, a quartz substrate, a sapphire substrate, or the like may be used as the substrate 102. Alternatively, any of these substrates on which a semiconductor element is provided may be used as the substrate 102.

A flexible substrate may be used as the substrate 102, and the semiconductor device may be formed directly on the flexible substrate. A separation layer may be provided between the substrate 102 and the semiconductor device. The separation layer can be used when part or the whole of a semiconductor device completed thereover is separated from the substrate 102 and transferred onto another substrate. In that case, the semiconductor device can be transferred to even a substrate having low heat resistance or a flexible substrate.

### Conductive Layer

The conductive layer 112, the conductive layer 106, the conductive layer 120a, the conductive layer 120b, the conductive layer 121a, the conductive layer 121b, the conductive layer 130, the conductive layer 150, and the like can each be formed using a metal element selected from chromium, copper, aluminum, gold, silver, zinc, molybdenum, tantalum, titanium, tungsten, manganese, nickel, iron, and cobalt; an alloy containing any of these metal elements as its component; an alloy including a combination of any of these metal elements; or the like.

An oxide conductor or a metal oxide film such as an In—Sn oxide, an In—W oxide, an In—W—Zn oxide, an In—Ti oxide, an In—Ti—Sn oxide, an In—Zn oxide, an In—Sn—Si oxide, or an In—Ga—Zn oxide can also be used for the conductive layer.

### Semiconductor Layer

In the case where the semiconductor layer 108 is an In—M—Zn oxide, examples of the atomic ratio of metal elements of a sputtering target used for depositing an In—M—Zn oxide include In:M:Zn=1:1:1, In:M:Zn=1:1:1.2, In:M:Zn=1:3:2, In:M:Zn=1:3:4, In:M:Zn=1:3:6, In:M:Zn=2:2:1, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5.

A target containing a polycrystalline oxide is preferably used as the sputtering target, in which case the semiconductor layer 108 having crystallinity is easily formed. Note that the atomic ratio in the semiconductor layer 108 to be deposited varies in the range of ±40% from any of the above atomic ratios of the metal elements contained in the sputtering target. For example, in the case where the composition of a sputtering target used for the semiconductor layer 108 is In:Ga:Zn=4:2:4.1 [atomic ratio], the composition of the semiconductor layer 108 to be deposited is sometimes in the neighborhood of In:Ga:Zn=4:2:3 [atomic ratio].

Note that when the atomic ratio is described as In:Ga:Zn=4:2:3 or in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or in the neighborhood thereof, the case is included where Ga is greater than 0.1 and less than or equal to 2 and Zn is greater than 0.1 and less than or equal to 2 with In being 1.

The energy gap of the semiconductor layer 108 is greater than or equal to 2 eV, preferably greater than or equal to 2.5 eV. With use of such a metal oxide having a wider energy gap than silicon, the off-state current of the transistor can be reduced.

The semiconductor layer 108 preferably has a non-single-crystal structure. The non-single-crystal structure includes, for example, a CAAC structure which is described later, a polycrystalline structure, a microcrystalline structure, and an amorphous structure. Among the non-single-crystal structures, the amorphous structure has the highest density of defect states, whereas the CAAC structure has the lowest density of defect states.

A CAAC (c-axis aligned crystal) is described below. A CAAC refers to an example of a crystal structure.

The CAAC structure is a crystal structure of a thin film or the like that has a plurality of nanocrystals (crystal regions having a maximum diameter of less than 10 nm), characterized in that the nanocrystals have c-axis alignment in a particular direction and are not aligned but continuously connected in the a-axis and b-axis directions without forming a grain boundary. In particular, a thin film having the CAAC structure is characterized in that the c-axes of nanocrystals are likely to be aligned in the film thickness direction, the normal direction of the surface where the thin film is formed, or the normal direction of the surface of the thin film.

A CAAC-OS (Oxide Semiconductor) is an oxide semiconductor with high crystallinity. Meanwhile, in the CAAC-OS, it can be said that a reduction in electron mobility due to the crystal grain boundary is less likely to occur because a clear crystal grain boundary cannot be observed. Moreover, since the crystallinity of an oxide semiconductor might be decreased by entry of impurities, formation of defects, or the like, the CAAC-OS can be regarded as an oxide semiconductor that has a small amount of impurities and defects (e.g., oxygen vacancies). Therefore, an oxide semiconductor including the CAAC-OS is physically stable. Accordingly, the oxide semiconductor including the CAAC-OS is resistant to heat and has high reliability.

Here, in crystallography, in a unit cell formed with three axes (crystal axes) of the a-axis, the b-axis, and the c-axis, a specific axis is generally taken as the c-axis in the unit cell. In particular, in the case of a crystal having a layered structure, two axes parallel to the plane direction of a layer are regarded as the a-axis and the b-axis and an axis intersecting with the layer is regarded as the c-axis in general. A typical example of such a crystal having a layered structure is graphite, which is classified as a hexagonal system. In a unit cell of graphite, the a-axis and the b-axis are parallel to the cleavage plane and the c-axis is orthogonal to the cleavage plane. For example, an InGaZnO₄ crystal having a YbFe₂O₄ type crystal structure which is a layered structure can be classified as a hexagonal system, and in a unit cell thereof, the a-axis and the b-axis are parallel to the plane direction of the layer and the c-axis is orthogonal to the layer (i.e., the a-axis and the b-axis).

In an image obtained with a TEM, crystal parts cannot be found clearly in an oxide semiconductor film having a microcrystalline structure (a microcrystalline oxide semiconductor film) in some cases. In most cases, the size of a crystal part included in the microcrystalline oxide semiconductor film is greater than or equal to 1 nm and less than or equal to 100 nm, or greater than or equal to 1 nm and less than or equal to 10 nm. In particular, an oxide semiconductor film including a nanocrystal (nc) that is a microcrystal with a size greater than or equal to 1 nm and less than or equal to 10 nm, or greater than or equal to 1 nm and less than or equal to 3 nm is referred to as an nc-OS (nanocrystalline Oxide Semiconductor) film. In an image of the nc-OS film observed with a TEM, for example, a crystal grain boundary cannot be clearly observed in some cases.

In the nc-OS film, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different crystal parts in the nc-OS film. Hence, the orientation in the whole film is not observed. Accordingly, the nc-OS film cannot be distinguished from an amorphous oxide semiconductor film by some analysis methods. For example, when the nc-OS film is subjected to structural analysis by an out-of-plane method with an XRD apparatus using an X-ray having a diameter larger than the diameter of a crystal part, a peak indicating a crystal plane does not appear. Furthermore, a diffraction pattern like a halo pattern is observed when the nc-OS film is subjected to electron diffraction using an electron beam with a probe diameter (e.g., 50 nm or larger) that is larger than the diameter of a crystal part (also referred to as selected-area electron diffraction). Meanwhile, in some cases, a circular (ring-like) region with high luminance is observed in an electron diffraction pattern (also referred to as nanobeam electron diffraction pattern) of the nc-OS film, which is obtained using an electron beam with a probe diameter close to or smaller than the diameter of a crystal part (e.g., 1 nm or larger and 30 nm or smaller), and spots are observed in the ring-like region.

The nc-OS film has a lower density of defect states than an amorphous oxide semiconductor film. Note that there is no regularity of crystal orientation between different crystal parts in the nc-OS film. Hence, the nc-OS film has a higher density of defect states than the CAAC-OS film. Thus, the nc-OS film has a higher carrier density and higher electron mobility than the CAAC-OS film in some cases. Accordingly, a transistor using the nc-OS film may have high field-effect mobility.

The nc-OS film can be formed at a lower oxygen flow rate ratio in deposition than the CAAC-OS film. The nc-OS film can also be formed at a lower substrate temperature in deposition than the CAAC-OS film. For example, the nc-OS film can be formed at a relatively low substrate temperature (e.g., a temperature of 130 °C or lower) or without heating of the substrate and thus is suitable for the case of using a large glass substrate, a resin substrate, or the like, and productivity can be increased.

An example of a crystal structure of a metal oxide is described. A metal oxide that is formed by a sputtering method using an In—Ga—Zn oxide target (In:Ga:Zn=4:2:4.1 [atomic ratio]) at a substrate temperature higher than or equal to 100 °C and lower than or equal to 130 °C is likely to have either the nc (nano crystal) structure or the CAAC structure, or a structure in which both structures are mixed. By contrast, a metal oxide formed at a substrate temperature set at room temperature (R.T.) is likely to have the nc crystal structure. Note that room temperature (R.T.) here also includes a temperature in the case where a substrate is not heated intentionally.

### Composition of Metal Oxide

The composition of a CAC (Cloud-Aligned Composite)-OS that can be used in a transistor disclosed in one embodiment of the present invention will be described below.

Note that a CAAC (c-axis aligned crystal) refers to an example of a crystal structure, and a CAC (Cloud-Aligned Composite) refers to an example of a function or a material composition.

A CAC-OS or a CAC-metal oxide has a conducting function in part of the material and has an insulating function in another part of the material; as a whole, the CAC-OS or the CAC-metal oxide has a function of a semiconductor. Note that in the case where the CAC-OS or the CAC-metal oxide is used in an active layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Furthermore, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, in some cases, the conductive regions are observed to be coupled in a cloud-like manner with their boundaries blurred.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, high current driving capability in an on state of the transistor, that is, a high on-state current and high field-effect mobility can be obtained.

In other words, the CAC-OS or the CAC-metal oxide can also be referred to as a matrix composite or a metal matrix composite.

The above is the description of the metal oxide structure.

At least part of the structure examples, the drawings corresponding thereto, and the like described in this embodiment as an example can be combined with the other structure examples, the other drawings, and the like as appropriate.

### Embodiment 2

In this embodiment, an example of a display device that includes the semiconductor device exemplified in the above embodiment is described.

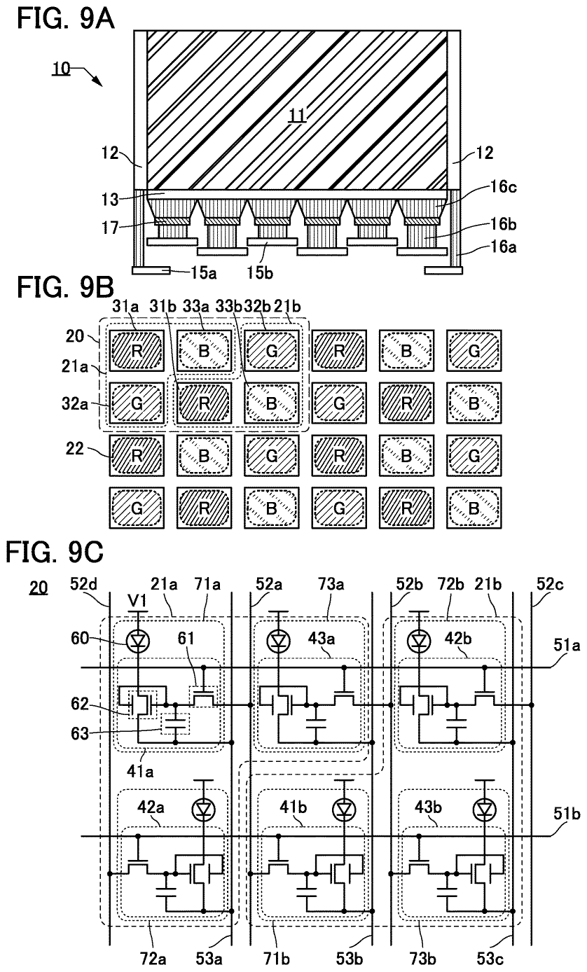

FIG. 9A is a schematic top view of a display device 10 described below as an example. The display device 10 includes a pixel portion 11, a circuit 12, a circuit 13, a terminal portion 15a, a terminal portion 15b, a wiring 16a, a wiring 16b, and a wiring 16c. FIG. 9A shows an example where an IC 17 is mounted on the display device 10.

The pixel portion 11 includes a plurality of pixels and has a function of displaying images.

The circuit 12 and the IC 17 each have a function of outputting signals for driving pixels of the pixel portion 11. The circuit 12 is a circuit serving as a gate driver circuit, for example. The IC 17 is a circuit serving as a source driver circuit, for example. FIG. 9A illustrates an example where two circuits 12 are provided with the pixel portion 11 therebetween and six ICs 17 are mounted. Note that an IC serving as a gate driver circuit may be mounted instead of the circuit 12. Alternatively, a source driver circuit may be provided instead of the IC 17.

Note that an embodiment in which an integrated circuit such as an IC or a connector such as an FPC (flexible printed circuit) is mounted can be referred to as a display module. Furthermore, an embodiment in which a connector, an integrated circuit, or the like is not mounted can be referred to as a display panel.

The circuit 13 is a circuit that has a function of distributing one signal input from the IC 17 to two or more wirings (e.g., a demultiplexer circuit). When the circuit 13 is provided, the number of signals output from the IC 17 can be reduced, so that the number of terminals of the IC 17 or the number of components can be reduced. In particular, in the case where ultra-high definition display devices, such as 4K and 8K display devices, are achieved, the provision of the circuit 13 is particularly effective. The circuit 13 may be omitted if not needed.

A plurality of terminals are provided in the terminal portion 15a and the terminal portion 15b, and a connector such as an FPC or another integrated circuit such as an IC can be connected. The terminals of the terminal portion 15a are each electrically connected to the circuit 12 through one of a plurality of wirings 16a. The terminals of the terminal portion 15b are each electrically connected to the IC 17 through one of a plurality of wirings 16b. A plurality of output terminals of the IC 17 are each electrically connected to the circuit 13 through one of a plurality of wirings 16c.

FIG. 9B is a schematic top view illustrating an arrangement example of pixel electrodes in the pixel portion 11. The pixel portion 11 includes a plurality of pixel units 20. There are four pixel units 20 in FIG. 9B. Each pixel unit 20 includes a pixel 21a and a pixel 21b. Each pixel 21a includes a pixel electrode 31a, a pixel electrode 32a, and a pixel electrode 33a. Each pixel 21b includes a pixel electrode 31b, a pixel electrode 32b, and a pixel electrode 33b. Each pixel electrode serves as an electrode of a display element, which is described below. A display region 22 of each subpixel is located inside its pixel electrode.

Six pixel electrodes of the pixel unit 20 are arranged in a matrix of two rows and three columns. The pixel electrode 31a, the pixel electrode 32a, and the pixel electrode 33a, which are electrodes of display elements, can exhibit different colors from each other. The pixel electrode 31b, the pixel electrode 32b, and the pixel electrode 33b can emit the same color as the pixel electrode 31a, the pixel electrode 32a, and the pixel electrode 33a, respectively. Although the three kinds of pixel electrodes are the same in size, they may differ in size. The display regions 22 may differ in size between the pixel electrodes.

For simplicity, a symbol R for representing an electrode of a display element that emits red (R) is added to the pixel electrode 31a. Similarly, a symbol G for representing an electrode of a display element that emits green (G) is added to the pixel electrode 32a, and a symbol B for representing an electrode of a display element that emits blue (B) is added to the pixel electrode 33a. Note that the pixel arrangement illustrated in FIG. 9B or the like is a non-limiting example. Furthermore, R, G, and B can be interchanged with one another. The pixel arrangement illustrated in FIG. 9B or the like can be laterally inverted or top-bottom inverted.

Note that the arrangement method of the display elements is not limited to the above, and what is called stripe arrangement may be employed in which three display elements each having a rectangular shape are arranged in one square, for example. Alternatively, what is called delta arrangement may be employed in which any of three display elements is provided at a vertex of a lattice formed by laying triangles each having the same shape close to each other.

### Structure Example of Pixel Circuit

An example of a pixel circuit included in the pixel unit 20 will be described. FIG. 9C illustrates an example of a circuit diagram of the pixel unit 20. A wiring 51a and a wiring 51b, a wiring 52a to a wiring 52d, and a wiring 53a to a wiring 53c are connected to the pixel unit 20. FIG. 9C illustrates an example of the case where four wirings (the wiring 52a and the like) functioning as signal lines are connected to one pixel unit 20.

The pixel 21a includes a subpixel 71a, a subpixel 72a, and a subpixel 73a. The pixel 21b includes a subpixel 71b, a subpixel 72b, and a subpixel 73b. Each subpixel includes a pixel circuit (a pixel circuit 41a, a pixel circuit 41b, a pixel circuit 42a, a pixel circuit 42b, a pixel circuit 43a, or a pixel circuit 43b) and a display element 60. For example, the subpixel 71a includes the pixel circuit 41a and the display element 60. A light-emitting element such as an organic EL element is used here as the display element 60.

In addition, each pixel circuit includes a transistor 61, a transistor 62, and a capacitor 63. In the pixel circuit 41a, for example, a gate of the transistor 61 is electrically connected to the wiring 51a, one of a source and a drain of the transistor 61 is electrically connected to the wiring 52a, and the other of the source and the drain is electrically connected to a gate of the transistor 62 and one electrode of the capacitor 63. One of a source and a drain of the transistor 62 is electrically connected to one electrode of the display element 60, and the other of the source and the drain is electrically connected to the other electrode of the capacitor 63 and the wiring 53a. The other electrode of the display element 60 is electrically connected to a wiring to which a potential V1 is applied. Note that the structures of other pixel circuits are similar to the pixel circuit 41a, except for a wiring to which the gate of the transistor 61 is connected, a wiring to which one of the source and the drain of the transistor 61 is connected, and a wiring to which the other electrode of the capacitor 63 is connected as illustrated in FIG. 9C.

In FIG. 9C, the transistor 61 has a function of a selection transistor. The transistor 62 is in a series connection with the display element 60 and has a function of controlling a current flowing into the display element 60. In FIG. 9C, the transistor 61 functioning as a selection transistor is electrically connected to one electrode (a pixel electrode) of the display element 60 through the transistor 62. The capacitor 63 has a function of holding the potential of a node connected to the gate of the transistor 62. Note that the capacitor 63 does not have to be intentionally provided in the case where an off-state leakage current of the transistor 61, a leakage current through the gate of the transistor 62, and the like are extremely small.

The transistor 62 preferably includes a first gate and a second gate electrically connected to each other as in FIG. 9C. This structure with the two gates can increase the amount of current that the transistor 62 can carry. Such a structure is particularly preferable for a high-resolution display device because the amount of current can be increased without increasing the size, the channel width in particular, of the transistor 62.

One of the pair of electrodes of the display element 60 which is electrically connected to the transistor 62 corresponds to the pixel electrode (e.g., the pixel electrode 31a). FIG. 9C illustrates a structure where an electrode of the display element 60 that is electrically connected to the transistor 62 is a cathode and the opposite electrode is an anode. This structure is particularly effective when the transistor 62 is an n-channel transistor. That is, when the transistor 62 is on, the potential applied by the wiring 53a is a source potential; accordingly, the amount of current flowing into the transistor 62 can be constant regardless of variation or change in electric resistance of the display element 60.

A structure may be employed in which the electrode of the display element 60 on the transistor 62 side serves as an anode and the electrode on the other side serves as a cathode. In the structure, a fixed potential which is lower than the potential applied to the wiring 53a and the like can be used as the potential V1, which is applied to the other electrode of the display element 60. The use of a potential common in a potential used in another circuit, such as a common potential or a ground potential, as the potential V1 leads to a simplification of the circuit structure, which is preferable.

Note that although an example is described in which an n-channel transistor is used as the transistor included in the pixel circuit here, a p-channel transistor may be used.

### Example of Pixel Layout

A layout example of the pixel unit 20 will be described.

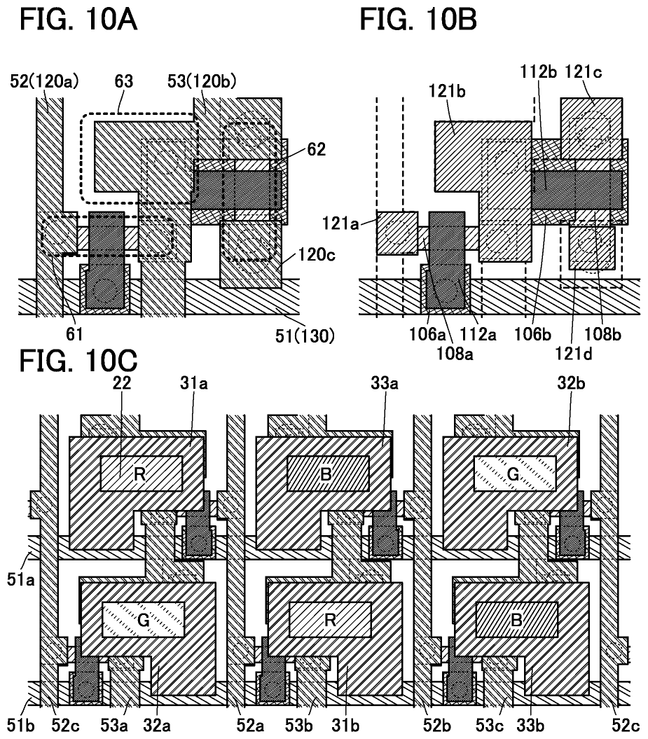

FIG. 10A and FIG. 10B each illustrate a layout example of one subpixel. The example shows, for easy viewing, a state before a pixel electrode is formed. Furthermore, in FIG. 10B, the wiring 52 and the like in FIG. 10A are denoted by a dashed line. The subpixel illustrated in FIG. 10A includes the transistor 61, the transistor 62, and the capacitor 63. The transistor 62 includes two gates with a semiconductor layer therebetween.

As the transistor 61 and the transistor 62, the transistors exemplified in Embodiment 1 can be used.

In FIG. 10A and the like, patterns formed by processing the same conductive film are shown with the same hatching pattern. A conductive layer (the conductive layer 130) positioned on the lowermost side forms the wiring 51. Conductive layers (the conductive layer 106a, the conductive layer 106b, and the like) formed after the formation of the wiring 51 form a relay wiring, one gate of the transistor 62, and the like. Conductive layers (the conductive layer 112a, the conductive layer 112b, and the like) formed after the formation of the relay wiring, the one gate of the transistor 62, and the like form a gate of the transistor 61, the other gate of the transistor 62, and the like. Conductive layers (the conductive layer 121a, the conductive layer 121b, the conductive layer 121c, the conductive layer 121d, and the like) formed after the formation of the gate of the transistor 61, the other gate of the transistor 62, and the like form a source electrode and a drain electrode of each transistor, one electrode of the capacitor 63, and the like. Conductive layers (the conductive layer 120a, the conductive layer 120b, the conductive layer 120c, and the like) formed after the formation of the source electrode and the drain electrode of each transistor, the one electrode of the capacitor 63, and the like form the wiring 52, the wiring 53, a relay wiring, and the like. Part of the wiring 53 functions as the other electrode of the capacitor 63. The conductive layer 120c functions as a relay wiring connecting the transistor 62, the pixel electrode 31, and the like. Furthermore, the transistor 61 includes a semiconductor layer 108a, and the transistor 62 includes a semiconductor layer 108b.

FIG. 10C is a layout example of the pixel unit 20 including the subpixel illustrated in FIG. 10A. FIG. 10C explicitly illustrates pixel electrodes and the display regions 22.

In this example, three subpixels electrically connected to the wiring 51a and three subpixels electrically connected to the wiring 51b are each bilaterally symmetrical. Therefore, in the structure in which same-color subpixels are arranged in a zigzag pattern in the extending direction of the wiring 52a or the like and are connected to one wiring serving as a signal line, wirings in the subpixels can have uniform length, so that variation in luminance between the subpixels can be suppressed.

Note that the display regions 22 of three subpixels electrically connected to the wiring 51a and the display regions 22 of three subpixels electrically connected to the wiring 51b may be arranged to be shifted by a half distance of the arrangement pitch in the extending direction of the wiring 51a. Accordingly, what is called delta arrangement can be achieved.

The above is the description of the layout example of the pixel.

According to the display device exemplified in this embodiment, an extremely high-resolution display device can be achieved. A display device that has improved display quality can be provided. A display device with improved viewing angle characteristics can be provided. A display device with improved aperture ratio can be provided.

At least part of the structure examples, the drawings corresponding thereto, and the like described in this embodiment as an example can be combined with the other structure examples, the other drawings, and the like as appropriate.

### Embodiment 3

In this embodiment, a cross-sectional structure example of the display device of one embodiment of the present invention will be described.

### Cross-Sectional Structure Example 1

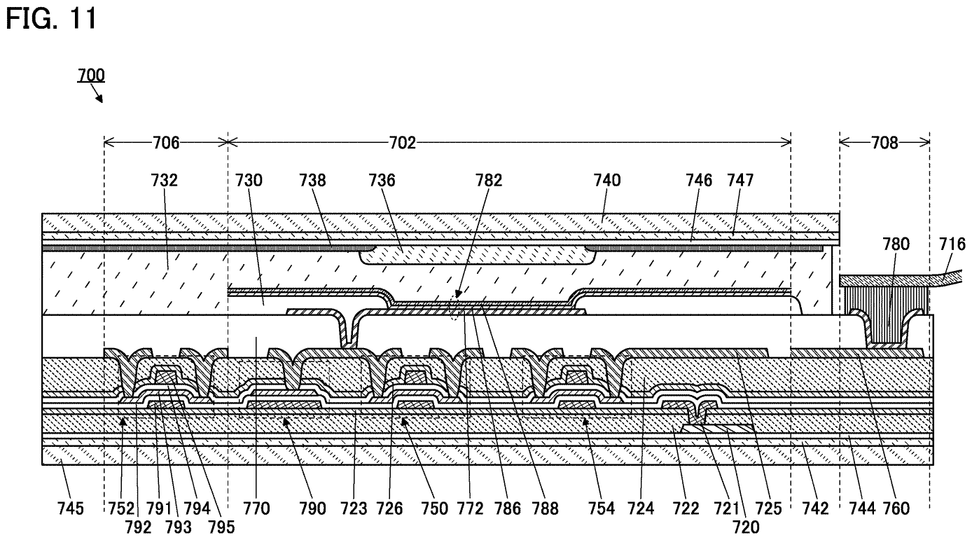

FIG. 11 is a cross-sectional schematic view of the display panel 700. FIG. 11 illustrates a cross section including the pixel portion 702, the gate driver circuit portion 706, and the FPC terminal portion 708. The pixel portion 702 includes a transistor 750, a transistor 754, and a capacitor 790. The gate driver circuit portion 706 includes a transistor 752

As the transistor 750, the transistor 752, and the transistor 754, any of the transistors described in Embodiment 1 as examples can be used.

The transistor 750, the transistor 752, and the transistor 754 are each a transistor using an oxide semiconductor for a semiconductor layer in which a channel is formed. Note that the transistors are not limited thereto, and a transistor using silicon (amorphous silicon, polycrystalline silicon, or single-crystal silicon) or a transistor using an organic semiconductor for the semiconductor layer can be used, for example.

The transistor used in this embodiment includes a highly purified oxide semiconductor film in which formation of oxygen vacancies is suppressed. The transistor can have an extremely low off-state current. Accordingly, in the pixel employing such a transistor, the retention time of an electric signal such as an image signal can be extended, and an interval between writings of an image signal or the like can also be set longer. Accordingly, the frequency of refresh operations can be reduced, so that power consumption can be reduced.

In addition, the transistor used in this embodiment can have comparatively high field-effect mobility and thus is capable of high-speed driving. For example, with such a transistor capable of high-speed driving used for the display panel, a switching transistor in a pixel portion and a driver transistor used in a driver circuit portion can be formed over the same substrate. In other words, a structure in which a driver circuit formed using a silicon wafer or the like is not employed is possible, and the number of components of the display device can be reduced. Furthermore, the use of the transistor capable of high-speed driving also in the pixel portion can provide a high-quality image.

The capacitor 790 includes a lower electrode formed by processing the same film as a film used for the first gate electrode of the transistor 750 and an upper electrode formed by processing the same metal oxide film as a film used for the semiconductor layer. The resistance of the upper electrode is reduced as that of a source region and a drain region of the transistor 750. In addition, part of an insulating film functioning as a first gate insulating layer of the transistor 750 is provided between the lower electrode and the upper electrode. That is, the capacitor 790 has a stacked-layer structure in which an insulating film functioning as a dielectric film is positioned between a pair of electrodes. A wiring obtained by processing the same film as a film used for a source electrode and a drain electrode of the transistor 750 is connected to the upper electrode.

The display panel 700 includes a support substrate 745 and a support substrate 740. As the support substrate 745 and the support substrate 740, a glass substrate or a substrate having flexibility such as a plastic substrate can be used, for example.

The transistor 750, the transistor 752, the transistor 754, the capacitor 790, and the like are provided over an insulating layer 744. The support substrate 745 and the insulating layer 744 are attached to each other with an adhesive layer 742.

A conductive layer 720 is provided over the insulating layer 744. A resin layer 722 is provided to cover the insulating layer 744 and the conductive layer 720. An insulating layer 723 is provided to cover the resin layer 722.

The transistor 750, the transistor 752, the transistor 754, the capacitor 790, and the like are provided over the insulating layer 723.

The transistor 750, the transistor 752, and the transistor 754 each include a conductive layer 791 functioning as a first gate electrode, an insulating layer 792 functioning as a first gate insulating layer, a semiconductor layer 793, an insulating layer 794 functioning as a second gate insulating layer, a conductive layer 795 functioning as a second gate electrode, and the like. Furthermore, an insulating layer 726 is provided to cover the transistor 750, the transistor 752, and the transistor 754.

A resin layer 724 is provided over the insulating layer 726, and a conductive layer 725 and the like are provided over the resin layer 724.

A conductive layer 721 formed by processing the same conductive film as the conductive layer 791 is electrically connected to the conductive layer 720 in an opening portion provided in the insulating layer 723 and the resin layer 722.

Part of the conductive layer 720 functions as a gate line. Part of the conductive layer 725 functions as a source line. Part of the conductive layer 720 and part of the conductive layer 725 overlap with each other with at least the resin layer 722 and the resin layer 724 therebetween.

An insulating layer 770 that functions as a planarization film is provided over the transistor 750, the transistor 752, the transistor 754, and the capacitor 790.

As the transistor 750 and the transistor 754 included in the pixel portion 702 and the transistor 752 included in the gate driver circuit portion 706, transistors having different structures may be used. For example, a top-gate transistor may be used as any of the transistors, and a bottom-gate transistor may be used as any of the others.

The FPC terminal portion 708 includes a wiring 760 part of which functions as a connection electrode, an anisotropic conductive film 780, and the FPC 716. The wiring 760 is electrically connected to a terminal included in the FPC 716 through the anisotropic conductive film 780. Here, the wiring 760 is formed using the same conductive film as the source electrode and the drain electrode of the transistor 750 and the like.

The display panel 700 includes a light-emitting element 782, a coloring layer 736, a light-blocking layer 738, and the like.

The light-emitting element 782 includes a conductive layer 772, an EL layer 786, and a conductive layer 788. The conductive layer 772 is electrically connected to the source electrode or the drain electrode included in the transistor 750. The conductive layer 772 is provided over the insulating layer 770 and functions as a pixel electrode. An insulating layer 730 is provided to cover an end portion of the conductive layer 772. Over the insulating layer 730 and the conductive layer 772, the EL layer 786 and the conductive layer 788 are stacked.

For the conductive layer 772, a material having a property of reflecting visible light can be used. For example, a material including aluminum, silver, or the like can be used. For the conductive layer 788, a material having a property of transmitting visible light can be used. For example, an oxide material including indium, zinc, tin, or the like is preferably used. Thus, the light-emitting element 782 is a top-emission light-emitting element, which emits light to the side opposite the formation surface (the support substrate 740 side).

The EL layer 786 contains an organic compound or an inorganic compound such as quantum dots. The EL layer 786 contains a light-emitting material that exhibits white light when a current flows.

As the light-emitting material, a fluorescent material, a phosphorescent material, a thermally activated delayed fluorescence (TADF) material, an inorganic compound (a quantum dot material or the like), or the like can be used. Examples of materials that can be used for quantum dots include a colloidal quantum dot material, an alloyed quantum dot material, a core-shell quantum dot material, a core quantum dot material, and the like.

The light-blocking layer 738 and the coloring layer 736 are provided on one surface of an insulating layer 746. The coloring layer 736 is provided in a position overlapping with the light-emitting element 782. The light-blocking layer 738 is provided in a region not overlapping with the light-emitting element 782 in the pixel portion 702. Furthermore, the light-blocking layer 738 may also be provided to overlap with the gate driver circuit portion 706 or the like.

The support substrate 740 is attached to the other surface of the insulating layer 746 with an adhesive layer 747. Furthermore, the support substrate 740 and the support substrate 745 are attached to each other with a sealing layer 732.

Here, for the EL layer 786 included in the light-emitting element 782, a light-emitting material that exhibits white light emission is used. White light emission by the light-emitting element 782 is colored by the coloring layer 736 to be emitted to the outside. The EL layer 786 is provided over the pixels that exhibit different colors. The pixels provided with the coloring layer 736 transmitting any of red (R), green (G), and blue (B) are arranged in a matrix in the pixel portion 702, so that the display panel 700 can perform full-color display.

A conductive film having a transmissive property and a reflective property may be used for the conductive layer 788. In that case, a microcavity structure is achieved between the conductive layer 772 and the conductive layer 788 such that light of a specific wavelength can be intensified to be emitted. Also at this time, a structure may be employed in which an optical adjustment layer for adjusting an optical distance is placed between the conductive layer 772 and the conductive layer 788 such that the thickness of the optical adjustment layer differs between pixels of different colors and accordingly the color purity of light emitted from each pixel is increased.

Note that a structure in which at least one of the coloring layer 736 or the optical adjustment layer is not provided may be employed when the EL layer 786 is formed into an island shape for each pixel or into a stripe shape for each pixel column, i.e., the EL layer 786 is formed by separate coloring. In that case, the EL layer 786 may be separately formed by a vacuum evaporation method using a shadow mask such as a metal mask, or the EL layer 786 may be processed into an island shape or a stripe shape by a photolithography method.

Here, an inorganic insulating film that functions as a barrier film having low permeability is preferably used for each of the insulating layer 744 and the insulating layer 746. With such a structure in which the light-emitting element 782, the transistor 750, and the like are interposed between the insulating layer 744 and the insulating layer 746, deterioration of them can be inhibited and a highly reliable display panel can be achieved.

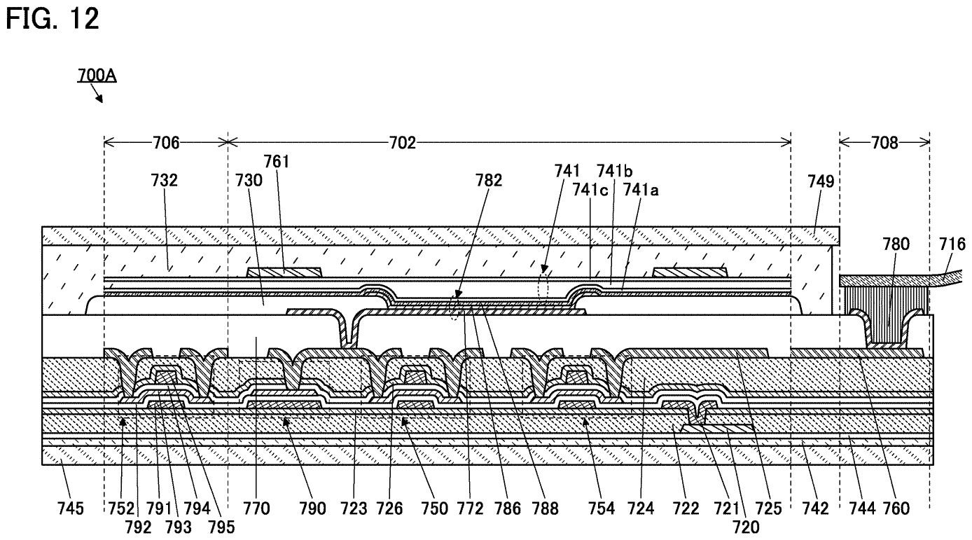

A display panel 700A illustrated in FIG. 12 includes a protective layer 749 instead of the support substrate 740.

The protective layer 749 is attached to the sealing layer 732. A glass substrate, a resin film, or the like can be used as the protective layer 749. Alternatively, as the protective layer 749, an optical member such as a polarizing plate (including a circularly polarizing plate) or a scattering plate, an input device such as a touch sensor panel, or a structure in which two or more of these are stacked may be employed.

The EL layer 786 included in the light-emitting element 782 is provided over the insulating layer 730 and the conductive layer 772 in an island shape. The EL layers 786 are formed separately so that respective subpixels emit light of different colors, so that color display can be performed without the use of the coloring layer 736.

A protective layer 741 is provided to cover the light-emitting element 782. The protective layer 741 has a function of preventing diffusion of impurities such as water into the light-emitting element 782. The protective layer 741 has a stacked-layer structure in which an insulating layer 741a, an insulating layer 741b, and an insulating layer 741c are stacked in this order from the conductive layer 788 side. In that case, it is preferable that inorganic insulating films with a high barrier property against impurities such as water be used as the insulating layer 741a and the insulating layer 741c and an organic insulating film that functions as a planarization film be used as the insulating layer 741b. Furthermore, the protective layer 741 is preferably provided to extend also to the gate driver circuit portion 706.

In FIG. 12, a conductive layer 761 is provided over the protective layer 741. The conductive layer 761 can be used as a wiring, an electrode, or the like.

In addition, in the case where a touch sensor is provided so as to overlap with the display panel 700A, the conductive layer 761 can function as an electrostatic shielding film for preventing transmission of electrical noise to the touch sensor during pixel driving. In that case, a structure in which a predetermined constant potential is applied to the conductive layer 761 may be employed.

Alternatively, the conductive layer 761 can be used as an electrode of the touch sensor, for example. This enables the display panel 700A to function as a touch panel. For example, the conductive layer 761 can be used as an electrode or a wiring of a capacitive touch sensor. In that case, the conductive layer 761 can be used as a wiring or an electrode to which a sensor circuit is connected or a wiring or an electrode to which a sensor signal is input, for example. When the touch sensor is formed over the light-emitting element 782 in this manner, the number of components can be reduced, and manufacturing cost of an electronic device or the like can be reduced.

The conductive layer 761 is preferably provided in a portion not overlapping with the light-emitting element 782. The conductive layer 761 can be provided in a position overlapping with the insulating layer 730, for example. Thus, a transparent conductive film with a comparatively low conductivity is not necessarily used for the conductive layer 761, and a metal or an alloy having high conductivity or the like can be used, so that the sensitivity of the sensor can be increased.

Note that as the type of the touch sensor that can be formed using the conductive layer 761, a variety of types such as a resistive type, a surface acoustic wave type, an infrared type, an optical type, and a pressure-sensitive type can be used, without limitation to a capacitive type. Alternatively, two or more of these types may be combined and used.

At least part of the structure examples, the drawings corresponding thereto, and the like described in this embodiment as an example can be combined with the other structure examples, the other drawings, and the like as appropriate.

### Embodiment 4

In this embodiment, an example of a head-mounted display including a display device will be described as an example of an electronic device of one embodiment of the present invention.

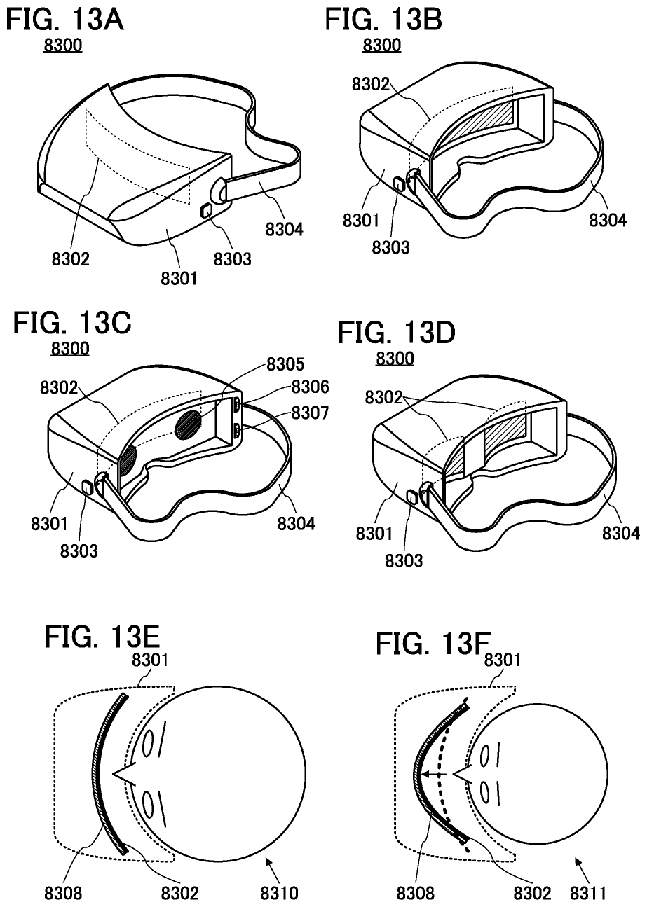

FIG. 13A and FIG. 13B are external views of a head-mounted display 8300.

The head-mounted display 8300 includes a housing 8301, a display portion 8302, an operation button 8303, and a band-like fixing member 8304.

The operation button 8303 functions as a power button or the like. Another button may be provided in addition to the operation button 8303.

As illustrated in FIG. 13C, lenses 8305 may be provided between the display portion 8302 and the user's eyes. The user can see magnified images on the display portion 8302 through the lenses 8305, thereby having a more realistic sensation. In this case, as illustrated in FIG. 13C, a dial 8306 for changing the position of the lenses and adjusting visibility may be provided.

The display device of one embodiment of the present invention can be used for the display portion 8302. Since the display device of one embodiment of the present invention has an extremely high resolution, even when images are magnified using the lenses 8305 as illustrated in FIG. 13C, the user does not perceive pixels, and thus, more realistic images can be displayed.

FIG. 13A to FIG. 13C illustrate examples in which the head-mounted display includes one display portion 8302. Such a structure can reduce the number of components.

The display portion 8302 can display an image for the right eye and an image for the left eye side by side on a right region and a left region, respectively. Thus, a three-dimensional image using binocular disparity can be displayed.

One image which can be seen with both eyes may be displayed on the entire display portion 8302. Thus, a panorama image can be displayed from end to end of the field of view, which can provide a higher sense of reality.

Here, the head-mounted display 8300 preferably has a mechanism for optimizing the curvature of the display portion 8302 in accordance with the size of the user's head, the position of the user's eyes, or the like. For example, the user himself/herself may adjust the curvature of the display portion 8302 by operating a dial 8307 for adjusting the curvature of the display portion 8302. Alternatively, the head-mounted display 8300 may include a sensor for detecting the size of the user's head, the position of the user's eyes, or the like (e.g., a camera, a contact sensor, and a noncontact sensor) on the housing 8301 and have a mechanism for adjusting the curvature of the display portion 8302 on the basis of data detected by the sensor.

In the case where the lenses 8305 are used, the head-mounted display 8300 preferably has a mechanism for adjusting the position and angle of the lenses 8305 in synchronization with the curvature of the display portion 8302. Alternatively, the dial 8306 may have a function of adjusting the angle of the lenses.

FIG. 13E and FIG. 13F illustrate an example of including a driver portion 8308 that controls the curvature of the display portion 8302. The driver portion 8308 is fixed to at least part of the display portion 8302. The driver portion 8308 has a function of changing the shape of the display portion 8302 when the part of the driver portion 8308 that is fixed to the display portion 8302 changes in shape or moves.

FIG. 13E is a schematic view illustrating the case where a user 8310 having a relatively large head wears the housing 8301. In that case, the driver portion 8308 adjusts the shape of the display portion 8302 so that the curvature is relatively small (the radius of curvature is large).

In contrast, FIG. 13F illustrates the case where a user 8311 having a smaller head than the user 8310 wears the housing 8301. The user 8311 has a shorter distance between the eyes than the user 8310. In that case, the driver portion 8308 adjusts the shape of the display portion 8302 so that the curvature is large (the radius of curvature is small). In FIG. 13F, the position and shape of the display portion 8302 in FIG. 13E are denoted by a dashed line.

When the head-mounted display 8300 has such a mechanism for adjusting the curvature of the display portion 8302, an optimal display can be offered to a variety of users of all ages and genders.

When the curvature of the display portion 8302 is changed in accordance with contents displayed on the display portion 8302, the user can have a more realistic sensation. For example, shaking can be expressed by vibrating the curvature of the display portion 8302. In this way, it is possible to produce various effects according to the scene in contents, and provide the user with new experiences. A further realistic display can be provided in conjunction with a vibration module provided in the housing 8301.

Note that the head-mounted display 8300 may include two display portions 8302 as illustrated in FIG. 13D.

When the two display portions 8302 are provided, the user's eyes can see their respective display portions. This allows a high-definition image to be displayed even when a three-dimensional display using parallax or the like is performed. In addition, the display portion 8302 is curved around an arc with an approximate center at the user's eye. This keeps a certain distance between the user's eye and the display surface of the display portion, enabling the user to see a more natural image. Furthermore, the user's eye is positioned in the normal direction of the display surface of the display portion; therefore, even when the luminance or chromaticity of light from the display portion is changed with the viewing angle, the influence of the change can be substantially ignorable and thus a more realistic image can be displayed.

At least part of the structure examples, the drawings corresponding thereto, and the like described in this embodiment as an example can be combined with the other structure examples, the other drawings, and the like as appropriate.

### Embodiment 5

In this embodiment, a display module that can be fabricated using one embodiment of the present invention is described.

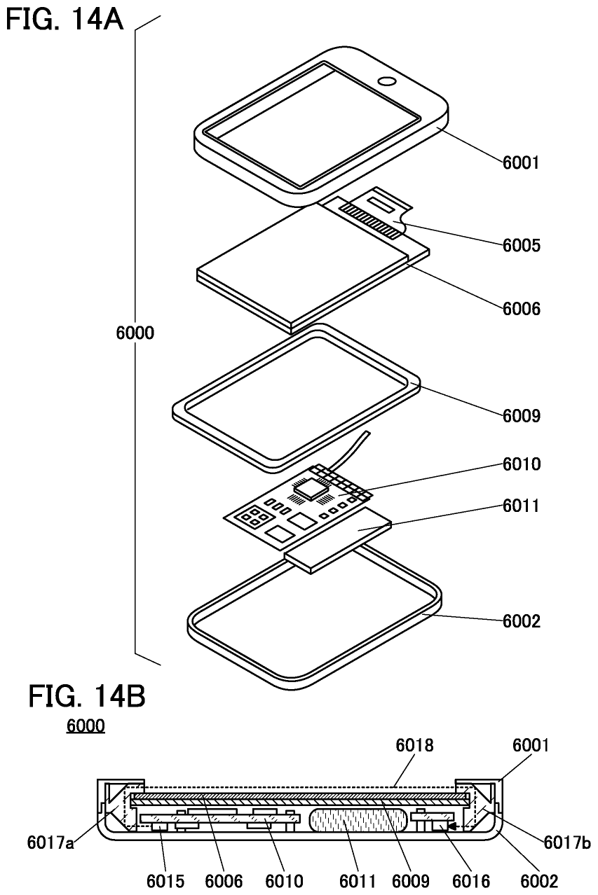

In a display module 6000 in FIG. 14A, a display device 6006 connected to an FPC 6005, a frame 6009, a printed circuit board 6010, and a battery 6011 are provided between an upper cover 6001 and a lower cover 6002.

For example, the display device fabricated using one embodiment of the present invention can be used as the display device 6006. With the display device 6006, a display module with extremely low power consumption can be achieved.

The shapes and sizes of the upper cover 6001 and the lower cover 6002 can be changed as appropriate in accordance with the size of the display device 6006.

The display device 6006 may function as a touch panel.

The frame 6009 may have a function of protecting the display device 6006, a function of blocking electromagnetic waves generated by the operation of the printed circuit board 6010, a function of a heat dissipation plate, or the like.

The printed circuit board 6010 includes a power supply circuit, a signal processing circuit for outputting a video signal and a clock signal, a battery control circuit, and the like.

FIG. 14B is a schematic cross-sectional view of the display module 6000 with an optical touch sensor.

The display module 6000 includes a light-emitting portion 6015 and a light-receiving portion 6016 which are provided on the printed circuit board 6010. A pair of light guide portions (a light guide portion 6017a and a light guide portion 6017b) is provided in a region surrounded by the upper cover 6001 and the lower cover 6002.

The display device 6006 overlaps with the printed circuit board 6010 and the battery 6011 with the frame 6009 therebetween. The display device 6006 and the frame 6009 are fixed to the light guide portion 6017a and the light guide portion 6017b.

Light 6018 emitted from the light-emitting portion 6015 travels over the display device 6006 through the light guide portion 6017a and reaches the light-receiving portion 6016 through the light guide portion 6017b. For example, blocking of the light 6018 by a sensing target such as a finger or a stylus can be detected as touch operation.

A plurality of light-emitting portions 6015 are provided along two adjacent sides of the display device 6006, for example. A plurality of light-receiving portions 6016 are provided at the positions on the opposite side of the light-emitting portions 6015. Accordingly, information about the position of touch operation can be obtained.

As the light-emitting portion 6015, a light source such as an LED element can be used. It is particularly preferable to use a light source that emits infrared light. As the light-receiving portion 6016, a photoelectric element that receives light emitted by the light-emitting portion 6015 and converts it into an electrical signal can be used. A photodiode that can receive infrared light can be favorably used.

With the use of the light guide portion 6017a and the light guide portion 6017b that transmit the light 6018, the light-emitting portion 6015 and the light-receiving portion 6016 can be placed under the display device 6006, and a malfunction of the touch sensor due to external light reaching the light-receiving portion 6016 can be inhibited. It is particularly preferable to use a resin that absorbs visible light and transmits infrared light, in which case the malfunction of the touch sensor can be inhibited more effectively.

At least part of this embodiment can be implemented in combination with the other embodiments described in this specification as appropriate.

### Embodiment 6

In this embodiment, examples of an electronic device for which the display device of one embodiment of the present invention can be used will be described.

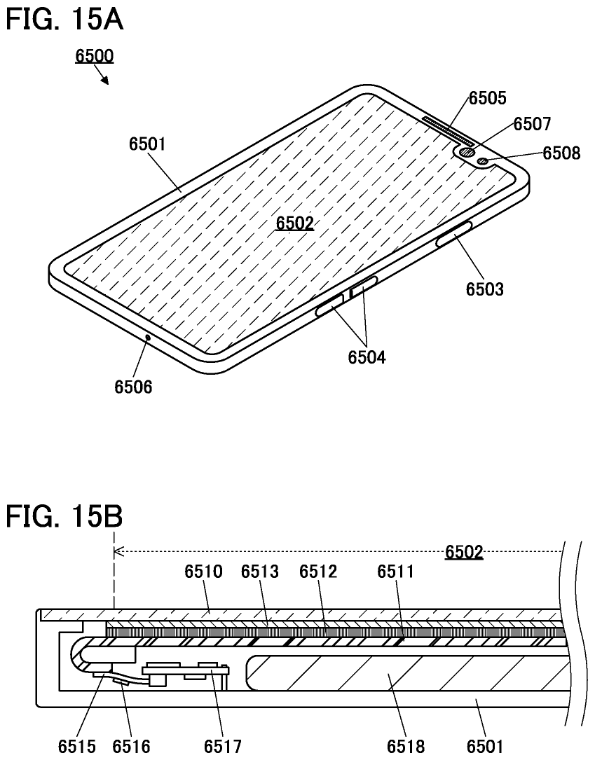

An electronic device 6500 in FIG. 15A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 15B is a schematic cross-sectional view including an end portion of the housing 6501 on the microphone 6506 side.

A protective member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with an adhesive layer not illustrated.

Part of the display panel 6511 is folded back in a region outside the display portion 6502. An FPC 6515 is connected to the folded part. An IC 6516 is mounted on the FPC 6515. The FPC 6515 is connected to a terminal provided on the printed circuit board 6517.

A flexible display panel of one embodiment of the present invention can be used as the display panel 6511. Thus, an extremely lightweight electronic device can be achieved. Furthermore, since the display panel 6511 is extremely thin, the battery 6518 with a high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

At least part of this embodiment can be implemented in combination with the other embodiments described in this specification as appropriate.

### Embodiment 7

In this embodiment, electronic devices each including a display device fabricated using one embodiment of the present invention will be described.

Electronic devices exemplified below are each provided with a display device of one embodiment of the present invention in a display portion. Thus, the electronic devices achieve high definition. In addition, the electronic devices can achieve both high definition and a large screen.

One embodiment of the present invention includes the display device and at least one of an antenna, a battery, a housing, a camera, a speaker, a microphone, a touch sensor, and an operation button.

The electronic device of one embodiment of the present invention may include a secondary battery. It is preferable that the secondary battery be capable of being charged by contactless power transmission.

Examples of the secondary battery include a lithium ion secondary battery such as a lithium polymer battery using a gel electrolyte (lithium ion polymer battery), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, or the like on a display portion. When the electronic device includes an antenna and a secondary battery, the antenna may be used for contactless power transmission.

The display portion of the electronic device of one embodiment of the present invention can display, for example, an image with full high definition, 4K2K, 8K4K, 16K8K, or higher definition.

Examples of electronic devices include electronic devices having relatively large screens, such as a television device, a laptop personal computer, a monitor, digital signage, a pachinko machine, and a game machine; a digital camera; a digital video camera; a digital photo frame; a mobile phone; a portable game console; a portable information terminal; an audio reproducing device; and the like.

An electronic device using one embodiment of the present invention can be incorporated along a flat surface or a curved surface of an inside wall or an outside wall of a building such as a house or a building, an interior or an exterior of a car, or the like.

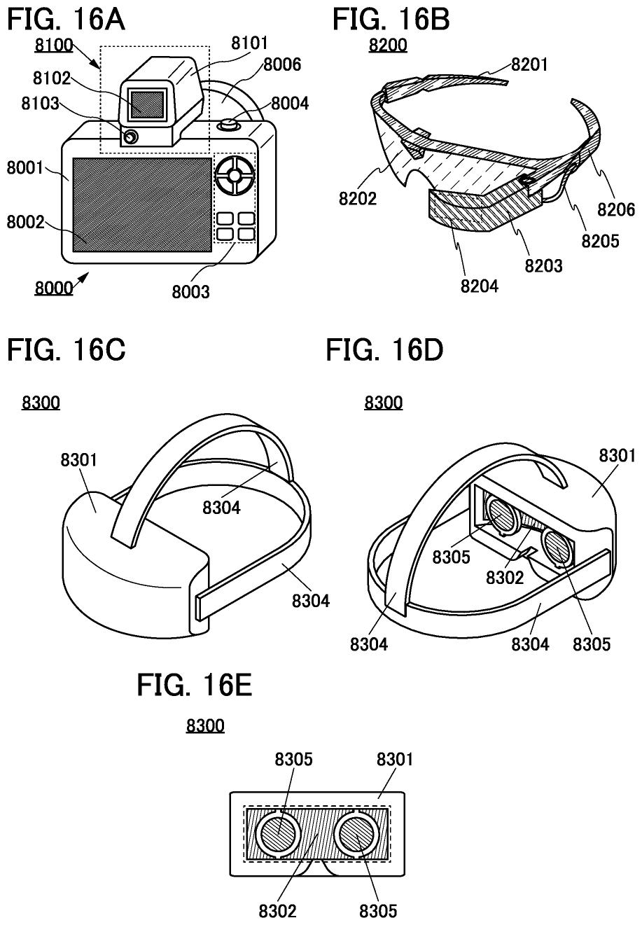

FIG. 16A is an external view of a camera 8000 to which a finder 8100 is attached.

The camera 8000 includes a housing 8001, a display portion 8002, operation buttons 8003, a shutter button 8004, and the like. Furthermore, a detachable lens 8006 is attached to the camera 8000.

Note that the lens 8006 may be included in the housing of the camera 8000.

The camera 8000 can take images by the press of the shutter button 8004 or touch on the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 by a mount for engagement with the mount of the camera 8000. The finder 8100 can display a video received from the camera 8000 and the like on the display portion 8102.

The button 8103 functions as a power supply button or the like.

A display device of one embodiment of the present invention can be used in the display portion 8002 of the camera 8000 and the display portion 8102 of the finder 8100. Note that a finder may be incorporated in the camera 8000.

FIG. 16B is an external view of a head-mounted display 8200.

The head-mounted display 8200 includes a mounting portion 8201, a lens 8202, a main body 8203, a display portion 8204, a cable 8205, and the like. The mounting portion 8201 includes a battery 8206.

Power is supplied from the battery 8206 to the main body 8203 through the cable 8205. The main body 8203 includes a wireless receiver or the like to receive image data and display it on the display portion 8204. The main body 8203 includes a camera, and data on the movement of the eyeballs or the eyelids of the user can be used as an input means.

The mounting portion 8201 may include a plurality of electrodes capable of sensing a current flowing accompanying with the movement of the user's eyeball at a position in contact with the user to recognize the user's sight line. The mounting portion 8201 may also have a function of monitoring the user's pulse with the use of a current flowing through the electrodes. The mounting portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, or the like.

A display device of one embodiment of the present invention can be used in the display portion 8204.

FIG. 16C, FIG. 16D, and FIG. 16E are external views of the head-mounted display 8300. The head-mounted display 8300 includes the housing 8301, the display portion 8302, the band-like fixing member 8304, and a pair of lenses 8305.

A user can see display on the display portion 8302 through the lenses 8305. The display portion 8302 is preferably curved because the user can feel high realistic sensation. Another image displayed in another region of the display portion 8302 is viewed through the lenses 8305, so that three-dimensional display using parallax or the like can be performed. Note that the number of display portions 8302 provided is not limited to one; two display portions 8302 may be provided so that one display portion is provided for one eye of the user.

A display device of one embodiment of the present invention can be used in the display portion 8302. A display device including the semiconductor device of one embodiment of the present invention has an extremely high resolution; thus, even when an image is magnified using the lenses 8305 as illustrated in FIG. 16E, the user does not perceive pixels, and thus a more realistic image can be displayed.

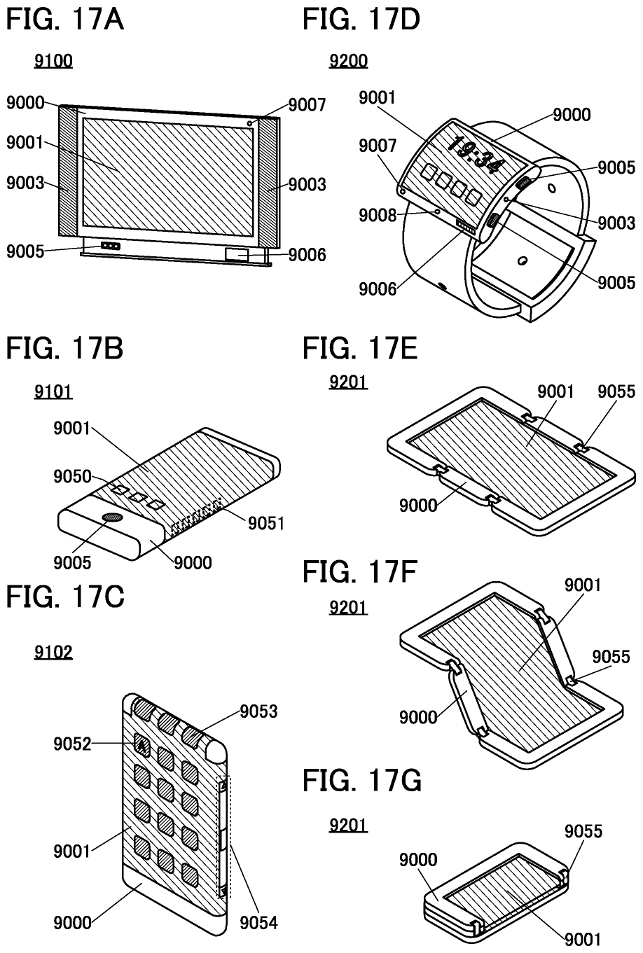

Electronic devices illustrated in FIG. 17A to FIG. 17G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIG. 17A to FIG. 17G have a variety of functions. For example, the electronic device can have a function of displaying a variety of information (a still image, a moving image, a text image, and the like) on the display portion, a touch panel function, a function of displaying a calendar, the date, the time, and the like, a function of controlling processing with a variety of software (programs), a wireless communication function, a function of reading a program or data stored in a storage medium and processing the program or data, and the like. Note that the electronic devices can have a variety of functions without limitation to the above. The electronic devices may each include a plurality of display portions. The electronic devices may each be provided with a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 17A to FIG. 17G are described in detail below.

FIG. 17A is a perspective view of a television device 9100. The television device 9100 can include the display portion 9001 having a large screen size of, for example, 50 inches or more, or 100 inches or more.

FIG. 17B is a perspective view of a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters, image information, or the like on its plurality of surfaces. In FIG. 17B, three icons 9050 are displayed as an example. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the reception strength of an antenna. Alternatively, the icon 9050 or the like may be displayed at the position where the information 9051 is displayed.

FIG. 17C is a perspective view of a portable information terminal 9102. The portable information terminal 9102 has a function of displaying information on three or more surfaces of the display portion 9001. Here, information 9052, information 9053, and information 9054 are displayed on different surfaces. For example, the user can check the information 9053 displayed in a position that can be observed from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 17D is a perspective view of a watch-type portable information terminal 9200. The display surface of the display portion 9001 is curved, and display can be performed along the curved display surface. Furthermore, for example, mutual communication between the portable information terminal 9200 and a headset capable of wireless communication can be performed, and thus hands-free calling is possible. The connection terminal 9006 of the portable information terminal 9200 allows mutual data transmission with another information terminal and charging. Note that the charging operation may be performed by wireless power feeding.

FIG. 17E, FIG. 17F, and FIG. 17G are perspective views of a foldable portable information terminal 9201. FIG. 17E is a perspective view of an opened state of the portable information terminal 9201, FIG. 17G is a perspective view of a folded state thereof, and FIG. 17F is a perspective view of a state in the middle of change from one of FIG. 17E and FIG. 17G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature of greater than or equal to 1 mm and less than or equal to 150 mm.

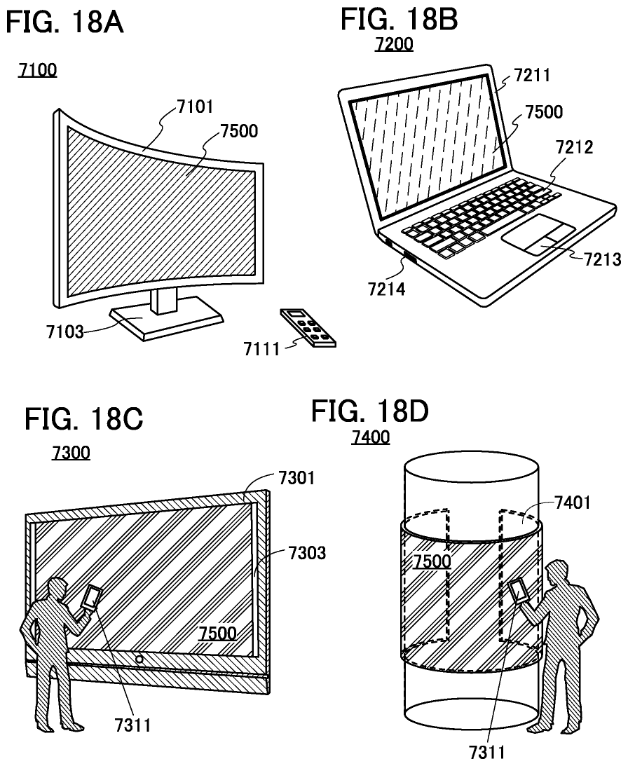

FIG. 18A illustrates an example of a television device. In a television device 7100, a display portion 7500 is incorporated in a housing 7101. Here, a structure in which the housing 7101 is supported by a stand 7103 is illustrated.

The television device 7100 illustrated in FIG. 18A can be operated with an operation switch provided in the housing 7101 or a separate remote controller 7111. Alternatively, a touch panel may be used in the display portion 7500 so that the television device 7100 can be operated by touching the touch panel. The remote controller 7111 may include a display portion in addition to operation buttons.

Note that the television device 7100 may include a television receiver and a communication device for a network connection.

FIG. 18B illustrates a laptop personal computer 7200. The laptop personal computer 7200 includes a housing 7211, a keyboard 7212, a pointing device 7213, an external connection port 7214, and the like. In the housing 7211, the display portion 7500 is incorporated.

FIG. 18C and FIG. 18D illustrate examples of digital signage.

Digital signage 7300 illustrated in FIG. 18C includes a housing 7301, the display portion 7500, a speaker 7303, and the like. The digital signage 7300 can also include an LED lamp, an operation key (including a power switch or an operation switch), a connection terminal, a variety of sensors, a microphone, and the like.

FIG. 18D is digital signage 7400 mounted on a cylindrical pillar 7401. The digital signage 7400 includes the display portion 7500 provided along a curved surface of the pillar 7401.

The larger display portion 7500 can provide a larger amount of information at a time and attract more attention, increasing the effectiveness of the advertisement, for example.

A touch panel is preferably used for the display portion 7500 so that the user can operate the digital signage. Thus, the digital signage can be used not only for advertising but also for providing information that the user needs, such as route information, traffic information, or guidance information on a commercial facility.

Furthermore, as illustrated in FIG. 18C and FIG. 18D, it is preferable that the digital signage 7300 or the digital signage 7400 work with an information terminal 7311 such as a user's smartphone through wireless communication. For example, information of an advertisement displayed on the display portion 7500 can be displayed on a screen of the portable information terminal 7311. Moreover, by operation of the information terminal 7311, a displayed image on the display portion 7500 can be switched.

Furthermore, it is possible to make the digital signage 7300 or the digital signage 7400 execute a game with the use of the information terminal 7311 as an operation means (controller). Thus, an unspecified number of users can join in and enjoy the game concurrently.

A display device of one embodiment of the present invention can be used in each of the display portions 7500 in FIG. 18A to FIG. 18D.

The electronic devices of this embodiment each include a display portion; however, one embodiment of the present invention can also be used in an electronic device without a display portion.

At least part of this embodiment can be implemented in combination with the other embodiments described in this specification as appropriate.

### REFERENCE NUMERALS

10: display device, 11: pixel portion, 12: circuit, 13: circuit, 15a and 15b: terminal portion, 16a-16c: wiring, 17: IC, 20: pixel unit, 21a-21b: pixel, 22: display region, 31-33: pixel electrode, 41-43: pixel circuit, 51-53: wiring, 60: display element, 61-62: transistor, 63: capacitor, 71-73: subpixel, 100: transistor, 102: substrate, 103a-103b: insulating layer, 104: insulating layer, 106, 106a, and 106b: conductive layer, 108, 108a, and 108b: semiconductor layer, 108n: low-resistance region, 110: insulating layer, 112, 112a, and 112b: conductive layer, 112f: conductive film, 114: metal oxide layer, 114f: metal oxide film, 116 and 118: insulating layer, 120a-120c: conductive layer, 121-121d: conductive layer, 130: conductive layer, 131-133: resin layer, 140: impurity element, 141a-141b: opening, 142-144: opening portion, 150: conductive layer

This application is based on Japanese Patent Application Serial No. 2020-190955 filed on Nov. 17, 2020, the entire contents are hereby incorporated herein by reference.

1. A portable information terminal comprising:
a display device including a pixel comprising a first transistor having a channel formation region in a first semiconductor layer, a second transistor having a channel formation region in a second semiconductor layer, and a light-emitting element,
wherein the portable information terminal is configured to allow the seamless display area to change from a folded state to an opened state, the portable information terminal comprising:
a first conductive layer;
an insulating layer comprising a region located above the first conductive layer;
a second conductive layer, a third conductive layer, a fourth conductive layer, and a fifth conductive layer each comprising a region located above the insulating layer;
a first layer comprising a region located above the second conductive layer, a region located above the third conductive layer, a region located above the fourth conductive layer, and a region located above the fifth conductive layer;
a sixth conductive layer, a seventh conductive layer, and an eighth conductive layer each comprising a region located above the first layer;
a second layer comprising a region located above the sixth conductive layer, a region located above the seventh conductive layer, and a region located above the eighth conductive layer; and
a ninth conductive layer comprising a region located above the second layer,
wherein the second conductive layer, the third conductive layer, the fourth conductive layer, and the fifth conductive layer each comprises a region in contact with an upper surface of the insulating layer,
wherein the sixth conductive layer, the seventh conductive layer, and the eighth conductive layer each have a region in contact with an upper surface of the first layer,
wherein each of the first layer and the second layer comprises resin,
wherein the first conductive layer is configured to be a first wiring for inputting a signal to a gate of the first transistor,
wherein the second conductive layer is configured to be electrically connected to the first semiconductor layer and a gate of the second transistor,
wherein the sixth conductive layer is configured to be a second wiring,
wherein a potential corresponding to a signal inputted to the second wiring is inputted to the gate of the second transistor through the channel formation region of the first transistor,
wherein the third conductive layer is electrically connected to the sixth conductive layer,
wherein the seventh conductive layer is configured to be a third wiring,
wherein the fourth conductive layer is configured to be electrically connected to the second semiconductor layer and the seventh conductive layer,
wherein the ninth conductive layer is configured to be a pixel electrode of the light-emitting element,
wherein the fifth conductive layer is configured to be electrically connected the second semiconductor layer and the ninth conductive layer,
wherein the eighth conductive layer is configured to be electrically connected the second semiconductor layer and the ninth conductive layer,
wherein the sixth conductive layer overlaps with the first conductive layer through the insulating layer and the first layer, and
wherein the seventh conductive layer overlaps with the first conductive layer through the insulating layer and the first layer.

2. The portable information terminal according to claim 1, wherein the seventh conductive layer is located so as to overlap the entirety of the second conductive layer through the first layer.

3. The portable information terminal according to claim 1,
wherein in a plan view of the pixel, the first conductive layer is located to extend in a first direction, and
wherein in the plan view, the sixth conductive layer is located to extend in a second direction intersecting the first direction.

4. The portable information terminal according to claim 1,
wherein the seventh conductive layer is located so as to overlap the entirety of the second conductive layer through the first layer,
wherein in a plan view of the pixel, the first conductive layer is located to extend in a first direction, and
wherein in the plan view, the sixth conductive layer is located to extend in a second direction intersecting the first direction.
